(19) United States
(12) Patent Application Publication
(10) Pub. No.: US 2015/0234003 A1
(43) Pub. Date: Aug. 20, 2015

(54) HIGH FREQUENCY MODULE

(71) Applicant: Panasonic Intellectual Property Management Co., Ltd., Osaka (JP)

(72) Inventors: RYOSUKE SHIOZAKI, Tokyo (JP); YUICHI KASHINO, Ishikawa (JP); SUGURU FUJITA, Tokyo (JP)

(21) Appl. No.: 14/702,633

(22) Filed: May 1, 2015

Related U.S. Application Data
(63) Continuation of application No. PCT/JP2014/003530, filed on Jul. 2, 2014.

(30) Foreign Application Priority Data
Jul. 17, 2013 (JP) 2013-148774

(51) Int. Cl. G01R 31/28

(52) U.S. Cl. CPC G01R 31/2822

(57) ABSTRACT

A high frequency module includes a module board, a connection member, and test terminals. The module board has a first surface on which a transmit antenna and a receive antenna are provided and a second surface on which a signal processing IC is provided, the second surface of the module board being the opposite side of the first surface. The connection member contains wiring for connecting the signal processing IC disposed on the second surface of the module board with another board. The test terminals are connected with the signal processing IC disposed on the second surface of the module board and arranged on the first surface of the module board.

### BACKGROUND

1. Technical Field

The present disclosure relates to a high frequency module including a board on which antennas for wireless communication are mounted.

2. Description of the Related Art

In a conventional design of a communication module having functions for wireless communication in a high frequency band, or a so-called high frequency module, antennas and signal processing circuits are implemented on separate boards. As wireless communication uses increasingly wide band and high frequency recently, however, some high frequency modules adopt a structure that integrates antennas and signal processing circuits because antennas can be small in size when handling radio signals in high frequency bands that are transmitted and received.

A high frequency module with integrated antennas is disclosed in Japanese Unexamined Patent Application Publication No. 2009-81833, for instance, in which antennas and high frequency circuits are contained in a single module. In Japanese Unexamined Patent Application Publication No. 2009-81833, the high frequency module with integrated antennas has patch antennas on one surface of the module board and high frequency circuits on the other side.

A high frequency module is equipped with test terminals for taking signals from circuits in the high frequency module for an inspection or failure analysis on the module. The test terminals need to be disposed at positions accessible from outside of the high frequency module. When signal processing circuits such as high frequency circuits are implemented within the module, test terminals are provided on a surface exposed to the outside.

A structure that adds a test pad to a high frequency module with integrated antennas is disclosed in Japanese Unexamined Patent Application Publication No. 2005-19649. FIG. 22 is a cross-sectional view showing the structure of the package for housing high frequency devices with integrated antennas as a conventional art described in Japanese Unexamined Patent Application Publication No. 2005-19649.

In the package for housing high frequency devices with integrated antennas in Japanese Unexamined Patent Application Publication No. 2005-19649, a hollow or recessed portion 13 is formed in the underside of dielectric substrates 11 and 12 which have an antenna conductor 21 formed on the upper surface, a high frequency device 31 is mounted in the hollow portion 13, and a connector 32 for measuring antenna characteristics is provided on the bottom surface of the hollow portion 13. The package for housing high frequency devices with integrated antennas is connected with a Printed Circuit Board 41 via an external terminal 26 disposed on the underside of the dielectric substrate 12 and is mounted in a communication device via the Printed Circuit Board 41. The Printed Circuit Board 41 has an opening 42 for connecting a measurement probe 35 to the antenna characteristics measurement connector 32 in the hollow portion 13 of the dielectric substrate 12.

### SUMMARY

As high frequency modules offer high performance and multiple functions, inspection or failure analysis on them is increasingly complicated and diverse, leading to an increasing trend in the number of test terminals included in a high frequency module. In a case in which antenna characteristics measurement connectors as test terminals are disposed on a surface of a dielectric substrate on which high frequency devices are implemented, as in the aforementioned conventional art, the area of the dielectric substrate can increase for accommodation of a large number of test terminals and the module could be difficult to adopt for a communication device of interest. Since such a design also requires formation of an opening in the Printed Circuit Board, its adoption can be difficult depending on the structure of the communication device in which the high frequency module is to be mounted.

One non-limiting and exemplary embodiment provides a high frequency module that allows mounting of test terminals while keeping the areas of boards from increasing.

In one general aspect, the techniques disclosed here feature a high frequency module including: a module board; antennas disposed on a first surface of the module board; signal processing circuits disposed on a second surface of the module board which is an opposite side of the first surface of the module board; a connection member connected with the module board and another board and containing wiring for the signal processing circuits; and one or more test terminals connected with the signal processing circuits and disposed on the first surface of the module board.

The present disclosure provides a high frequency module that allows mounting of test terminals while keeping the areas of boards from increasing.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1A is a plan view depicting the structure of a high frequency module according to a first embodiment of the present disclosure seen from above on the antenna side;

FIG. 1B is a lateral cross-sectional view of the high frequency module in the first embodiment of the present disclosure;

FIG. 2 illustrates the first example of arrangement of antennas and test terminals on a module board in the first embodiment;

FIG. 3A illustrates the second example of arrangement of antennas and test terminals on the module board in the first embodiment;

FIG. 3B illustrates a first variation of the second example of arrangement of antennas and test terminals on the module board in the first embodiment;

FIG. 3C illustrates a second variation of the second example of arrangement of antennas and test terminals on the module board in the first embodiment;

FIG. 4 illustrates the state of contact of test probes during an inspection or failure analysis on the module board;

FIG. 5A illustrates the first example of arrangement of antennas and test terminals on the module board of the high frequency module in a second embodiment of the present disclosure;

FIG. 5B illustrates the second example of arrangement of antennas and test terminals on the module board of the high frequency module in the second embodiment of the present disclosure;

FIG. 5C illustrates the third example of arrangement of antennas and test terminals on the module board of the high frequency module in the second embodiment of the present disclosure;

FIG. 5D illustrates the fourth example of arrangement of antennas and test terminals on the module board of the high frequency module in the second embodiment of the present disclosure;

FIG. 6A illustrates the first example of arrangement of antennas and test terminals on the module board of the high frequency module in a third embodiment of the present disclosure;

FIG. 6B illustrates the second example of arrangement of antennas and test terminals on the module board of the high frequency module in the third embodiment of the present disclosure;

FIG. 6C illustrates the third example of arrangement of antennas and test terminals on the module board of the high frequency module in the third embodiment of the present disclosure;

FIG. 6D illustrates the fourth example of arrangement of antennas and test terminals on the module board of the high frequency module in the third embodiment of the present disclosure;

FIG. 7A illustrates the first example of arrangement of antennas on the module board of the high frequency module in a fourth embodiment of the present disclosure;

FIG. 7B illustrates the second example of arrangement of antennas on the module board of the high frequency module in the fourth embodiment of the present disclosure;

FIG. 7C illustrates the third example of arrangement of antennas on the module board of the high frequency module in the fourth embodiment of the present disclosure;

FIG. 7D illustrates the fourth example of arrangement of antennas on the module board of the high frequency module in the fourth embodiment of the present disclosure;

FIG. 8A illustrates the first example of arrangement of antennas and test terminals on the module board of the high frequency module in a fifth embodiment of the present disclosure;

FIG. 8B illustrates the second example of arrangement of antennas and test terminals on the module board of the high frequency module in the fifth embodiment of the present disclosure;

FIG. 8C illustrates the third example of arrangement of antennas and test terminals on the module board of the high frequency module in the fifth embodiment of the present disclosure;

FIG. 8D illustrates the fourth example of arrangement of antennas and test terminals on the module board of the high frequency module in the fifth embodiment of the present disclosure;

FIG. 9A illustrates the first example of arrangement of antennas and test terminals on the module board of the high frequency module in a sixth embodiment of the present disclosure;

FIG. 9B illustrates the second example of arrangement of antennas and test terminals on the module board of the high frequency module in the sixth embodiment of the present disclosure;

FIG. 9C illustrates the third example of arrangement of antennas and test terminals on the module board of the high frequency module in the sixth embodiment of the present disclosure;

FIG. 9D illustrates the fourth example of arrangement of antennas and test terminals on the module board of the high frequency module in the sixth embodiment of the present disclosure;

FIG. 10A illustrates the first example of arrangement of antennas and test terminals on the module board of the high frequency module in a seventh embodiment of the present disclosure;

FIG. 10B illustrates the second example of arrangement of antennas and test terminals on the module board of the high frequency module in the seventh embodiment of the present disclosure;

FIG. 10C illustrates the third example of arrangement of antennas and test terminals on the module board of the high frequency module in the seventh embodiment of the present disclosure;

FIG. 10D illustrates the fourth example of arrangement of antennas and test terminals on the module board of the high frequency module in the seventh embodiment of the present disclosure;

FIG. 11 is a lateral cross-sectional view showing the structure of the high frequency module in the seventh embodiment;

FIG. 12A illustrates the first example of arrangement of antennas and test terminals on the module board of the high frequency module in an eighth embodiment of the present disclosure;

FIG. 12B illustrates the second example of arrangement of antennas and test terminals on the module board of the high frequency module in the eighth embodiment of the present disclosure;

FIG. 12C illustrates the third example of arrangement of antennas and test terminals on the module board of the high frequency module in the eighth embodiment of the present disclosure;

FIG. 12D illustrates the fourth example of arrangement of antennas and test terminals on the module board of the high frequency module in the eighth embodiment of the present disclosure;

FIG. 13A illustrates the first example of arrangement of antennas and test terminals on the module board of the high frequency module in a ninth embodiment of the present disclosure;

FIG. 13B illustrates the second example of arrangement of antennas and test terminals on the module board of the high frequency module in the ninth embodiment of the present disclosure;

FIG. 13C illustrates the third example of arrangement of antennas and test terminals on the module board of the high frequency module in the ninth embodiment of the present disclosure;

FIG. 13D illustrates the fourth example of arrangement of antennas and test terminals on the module board of the high frequency module in the ninth embodiment of the present disclosure;

FIG. 14A illustrates the first example of arrangement of antennas and test terminals on the module board of the high frequency module in a tenth embodiment of the present disclosure;

FIG. 14B illustrates the second example of arrangement of antennas and test terminals on the module board of the high frequency module in the tenth embodiment of the present disclosure;

FIG. 14C illustrates the third example of arrangement of antennas and test terminals on the module board of the high frequency module in the tenth embodiment of the present disclosure;

FIG. 14D illustrates the fourth example of arrangement of antennas and test terminals on the module board of the high frequency module in the tenth embodiment of the present disclosure;

FIG. 15A illustrates the first example of arrangement of antennas and test terminals on the module board of the high frequency module in an eleventh embodiment of the present disclosure;

FIG. 15B illustrates the second example of arrangement of antennas and test terminals on the module board of the high frequency module in the eleventh embodiment of the present disclosure;

FIG. 15C illustrates the third example of arrangement of antennas and test terminals on the module board of the high frequency module in the eleventh embodiment of the present disclosure;

FIG. 15D illustrates the fourth example of arrangement of antennas and test terminals on the module board of the high frequency module in the eleventh embodiment of the present disclosure;

FIG. 16A illustrates the first example of arrangement of antennas and test terminals on the module board of the high frequency module in a twelfth embodiment of the present disclosure;

FIG. 16B illustrates the second example of arrangement of antennas and test terminals on the module board of the high frequency module in the twelfth embodiment of the present disclosure;

FIG. 16C illustrates the third example of arrangement of antennas and test terminals on the module board of the high frequency module in the twelfth embodiment of the present disclosure;

FIG. 16D illustrates the fourth example of arrangement of antennas and test terminals on the module board of the high frequency module in the twelfth embodiment of the present disclosure;

FIG. 17A illustrates the first example of arrangement of antennas and test terminals on the module board of the high frequency module in a thirteenth embodiment of the present disclosure;

FIG. 17B illustrates the second example of arrangement of antennas and test terminals on the module board of the high frequency module in the thirteenth embodiment of the present disclosure;

FIG. 17C illustrates the third example of arrangement of antennas and test terminals on the module board of the high frequency module in the thirteenth embodiment of the present disclosure;

FIG. 17D illustrates the fourth example of arrangement of antennas and test terminals on the module board of the high frequency module in the thirteenth embodiment of the present disclosure;

FIG. 18A illustrates the first example of arrangement of antennas and test terminals on the module board of the high frequency module in a fourteenth embodiment of the present disclosure;

FIG. 18B illustrates the second example of arrangement of antennas and test terminals on the module board of the high frequency module in the fourteenth embodiment of the present disclosure;

FIG. 18C illustrates the third example of arrangement of antennas and test terminals on the module board of the high frequency module in the fourteenth embodiment of the present disclosure;

FIG. 19A illustrates the first example of arrangement of antennas and test terminals on the module board of the high frequency module in a fifteenth embodiment of the present disclosure;

FIG. 19B illustrates the second example of arrangement of antennas and test terminals on the module board of the high frequency module in the fifteenth embodiment of the present disclosure;

FIG. 19C illustrates the third example of arrangement of antennas and test terminals on the module board of the high frequency module in the fifteenth embodiment of the present disclosure;

FIG. 19D illustrates the fourth example of arrangement of antennas and test terminals on the module board of the high frequency module in the fifteenth embodiment of the present disclosure;

FIG. 20 is a lateral cross-sectional view showing the structure of the high frequency module in a sixteenth embodiment;

FIG. 21A is a cross-sectional view showing the structure of a test terminal portion of the module board of the high frequency module in a seventeenth embodiment;

FIG. 21B is a cross-sectional view showing a test terminal portion as a comparative example to that of the module board of the high frequency module in the seventeenth embodiment;

FIG. 22 is a cross-sectional view showing the structure of a package for housing high frequency devices with integrated antennas as an example of conventional art;

FIG. 23A is a plan view of an exemplary structure of a high frequency module that has test terminals provided on a Printed Circuit Board to be connected with a module board seen from above on the antenna side; and

FIG. 23B is a lateral cross-sectional view of a structure with test terminals provided on a Printed Circuit Board to be connected with the module board of a high frequency module.

### DETAILED DESCRIPTION

### <Underlying Knowledge Forming Basis of the Present Disclosure>

Before describing the embodiments of the high frequency module according to the present disclosure, challenges encountered in implementing test terminals on a high frequency module with integrated antennas will be discussed.

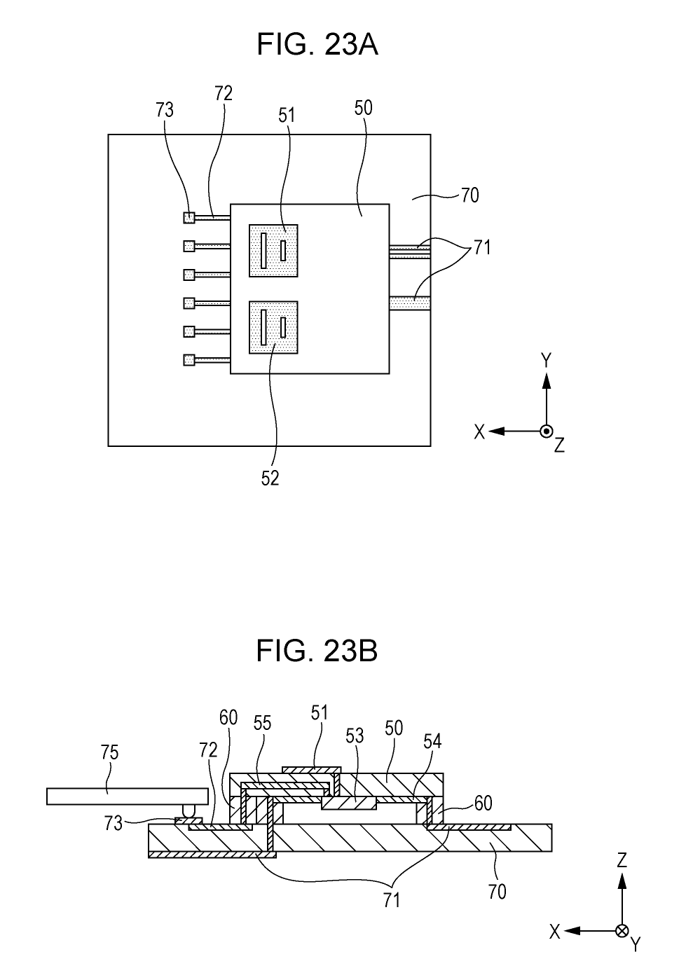

FIG. 23A is a plan view of an exemplary structure of a high frequency module that has test terminals on a Printed Circuit Board to be connected with the module board seen from above on the antenna side. FIG. 23B is a lateral cross-sectional view of an exemplary structure in which test terminals are provided on a Printed Circuit Board to be connected with the module board of a high frequency module.

The illustrated high frequency module has a cavity structure in which a module board 50 is connected with a Printed Circuit Board 70 via connection members 60, which are formed of a frame board for example, and the high frequency module is mounted in a communication device via the Printed Circuit Board 70. On one side of the module board 50, a transmit antenna 51 and a receive antenna 52 are mounted, and a signal processing integrated circuit (IC) 53 including high frequency circuits is implemented on the other side. On the module board 50, circuit wiring 54 including, for example, power supply wire, communication signal wire, and/or IC controlling signal wire, and test wiring 55 used for inspection or failure analysis are provided in the form of circuit patterns.

On the Printed Circuit Board 70, circuit wiring 71 including power supply wire, communication signal wire, and/or IC controlling signal wire, and test wiring 72 which is test signal wire used for inspection or failure analysis are provided in the form of circuit patterns. At an end of the test wiring 72, test terminals 73 formed from pad conductors, for example, are provided. The signal processing IC 53 needs to be checked for whether it operates normally after being implemented on the module board 50 or analyzed for the status of a failure in the event of a failure.

By providing the test terminals 73 on the Printed Circuit Board 70, the high frequency module illustrated in FIGS. 23A and 23B permits an inspection and failure analysis to be carried out using test equipment or with components mounted on the Printed Circuit Board 70 or in a communication device via the test terminals 73. The high frequency module is inspected or analyzed for a failure by making the test probe 75 into contact with the test terminals 73 to establish electrical conduction between them and detecting, for example, a voltage, current, or signal level value with the test terminals 73.

In the high frequency module, power supply wire, communication signal wire, IC controlling signal wire, and/or test signal wire, for example, is allocated to terminals present at connections of the module board 50, the connection members 60, and the Printed Circuit Board 70. As high frequency modules offer increasingly high performance and multiple functions, their inspection or failure analysis have become complicated and diverse and the number of test terminals tends to be large.

For a high frequency module that has test terminals 73 on the Printed Circuit Board 70, the Printed Circuit Board 70 and the connection members 60 need to be provided with wiring and terminals for tests in addition to wiring used for power supply and communication signals. One challenge of high frequency modules is increase in the areas of the module board 50 and the Printed Circuit Board 70 associated with increase in the number of terminals at connections for accommodating a large number of test terminals.

For example, a high frequency module requires double provision of terminals for laying out test terminal wiring in the connection members 60 as shown in FIG. 23B, which necessitates increasing the size of the connection members 60. Alternatively, when a required number of test terminals cannot be provided in a high frequency module due to an insufficient number of terminals, a mechanism for switching test wirings with a switch will be needed. Also, decrease in the number of ground (GND) terminals as a result of increase in test terminals can lead to degradation in communication performance of the high frequency module.

The aforementioned high frequency module structure described in Japanese Unexamined Patent Application Publication No. 2005-19649 has the problems of increase in the area of the dielectric substrate and increase in costs because it includes connectors formed of switches for measuring antenna characteristics as test terminals. Additionally, as the Printed Circuit Board varies in design from one communication device to another, a special structure such as forming an opening immediately below the dielectric substrate can be difficult to adopt with some Printed Circuit Boards.

In view of these challenges, the present disclosure will present exemplary structures of a high frequency module that can avoid an increase in the areas of boards due to mounting of test terminals.

### Embodiments of the Present Disclosure

Embodiments of the present disclosure will be described in detail below with reference to drawings. In the figures used in the following description, the same elements are given the same reference characters and overlapping descriptions will be omitted.

### First Embodiment

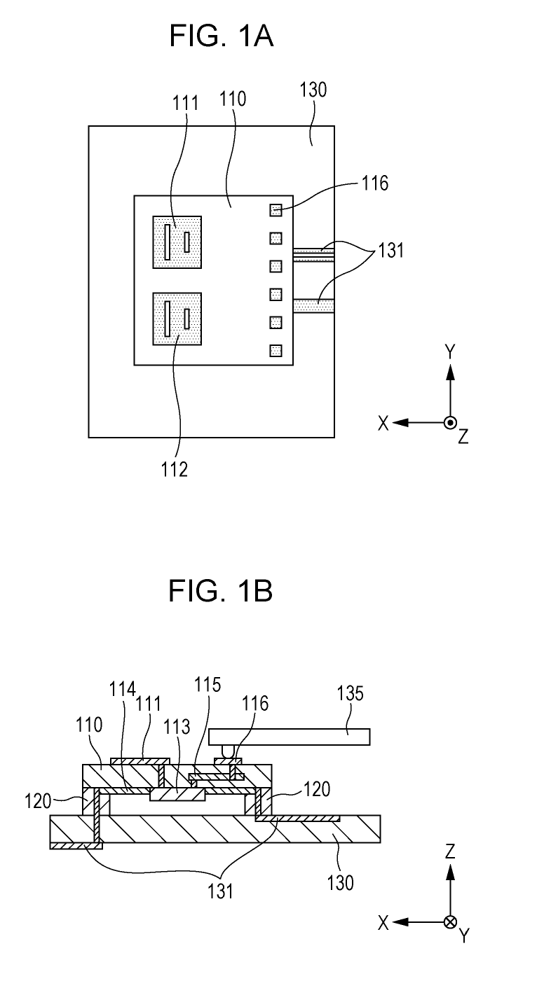

FIG. 1A is a plan view depicting the structure of a high frequency module according to a first embodiment of the present disclosure seen from above on the antenna side; and FIG. 1B is a lateral cross-sectional view of the high frequency module in the first embodiment of the present disclosure.

The high frequency module in this embodiment has a cavity structure in which a module board 110 having antennas thereon is connected with a Printed Circuit Board 130 via connection members 120, which may be a frame board (a cavity frame) for example, so as to face the Printed Circuit Board 130. The high frequency module is mounted in a communication device via the Printed Circuit Board 130. On the module board 110, a transmit antenna 111 and a receive antenna 112 are disposed on a first surface, which is exposed to the outside, while a signal processing IC 113 as an example of a signal processing circuit is implemented on a second surface which is the opposite side of the first surface.

FIG. 1A illustrates an exemplary structure in which the transmit antenna 111 and the receive antenna 112 which are slot antennas formed from electrically conductive patterns are disposed as an example of antennas provided on the module board 110. The module board 110, including test terminals 116, is covered with resist or dielectric. The antennas may be either covered or not covered with dielectric or resist.

The signal processing IC 113 is a semiconductor circuit element that includes high frequency circuits for performing processing relating to transmission and reception of high frequency signals in a radio frequency (RF) band and baseband circuits for processing outgoing and incoming signals in a baseband (BB). A frequency band of 30 GHz or higher is used for the frequency band of high frequency signals transmitted and received by the high frequency module of this embodiment, and 60-GHz band or 76 GHz, for example, is used for a millimeter wave band. An arrangement is also possible in which the signal processing IC 113 performs processing for the RF band and a separate circuit connected with the high frequency module performs processing for the baseband. The transmit antenna 111 and the receive antenna 112 are designed to yield the maximum radiation efficiency in a 30-GHz or higher band.

On the module board 110, circuit wiring 114 including power supply wire, communication signal wire, and/or IC controlling signal wire, and test wiring 115 used for inspection or failure analysis are provided in the form of electrically conductive circuit patterns. The circuit wiring 114 and the test wiring 115 are formed of a wiring pattern and through holes on the surface of and within the board.

Connection members 120 are connected with the second surface of the module board 110, the module board 110 being connected with the Printed Circuit Board 130 via the connection members 120. The Printed Circuit Board 130 is a board member for mounting the high frequency module in a device. On the Printed Circuit Board 130, circuit wiring 131 including power supply wire, communication signal wire, and/or IC controlling signal wire is provided in the form of an electrically conducive circuit pattern.

On the first surface of the module board 110, on which the transmit antenna 111 and the receive antenna 112 are disposed, test terminals 116 formed from pad conductors, for example, are provided. The test terminals 116 are used for inspection and failure analysis. One end of the test wiring 115 is connected with the signal processing IC 113 and the other end is connected with the test terminals 116. Test signals are transmitted and received through the test terminals 116. The test terminals 116 are pads electrically connected to the ground as well as to the signal processing IC 113, where the size of the pads can be determined as desired.

An inspection or failure analysis on the high frequency module is carried out by bringing the test probe 135 into contact with the test terminals 116 to establish electrical conduction between them and detecting at least one of voltage, current, and signal level values, for example, with the test terminals 116. Inspection or diagnosis may include checking of DC voltage at different points in circuits within the signal processing IC 113, checking of voltage and current at certain points in circuits, and sampling or monitoring of high frequency signals or baseband signals themselves (signals between circuit blocks) that are processed in circuits (or passing through circuits), for example. Such an inspection or failure analysis on the high frequency module may be carried out by supplying a certain power and inputting a predetermined test signal to check voltage and current, and/or signals at different locations, or monitoring signals output by a circuit itself, for example, a clock.

In this embodiment, the test terminals 116 are provided on the first surface of the module board 110, on which the antennas are disposed. On the Printed Circuit Board 130, no test wiring or test terminals are provided. On a surface of the high frequency module, accordingly, the test terminals 116 are disposed in addition to the transmit antenna 111 and the receive antenna 112. The transmit antenna 111, the receive antenna 112, and the test terminals 116 are connected with the signal processing IC 113 by the test wiring 115.

The high frequency module according to this embodiment eliminates the necessity to dispose test terminals for inspection or failure analysis, which are not used when data transmission and reception are performed by the high frequency module, on the second surface (or the underside) of the module board 110. The areas of the connection members 120 in the high frequency module can therefore be small. In addition, since the high frequency module does not require test terminals to be provided on the Printed Circuit Board 130, the number of terminals in the connection members 120, which connects the module board with the Printed Circuit Board 130, can be kept from increasing and the area of the Printed Circuit Board 130 can be also made small. As the test terminals 116 can be disposed in free space where no antenna is present on the first surface of the module board 110, the area of the module board 110 of the high frequency module can be kept from increasing. The high frequency module therefore can be made compact in size.

Advantageously, for a high frequency module that performs wireless communication in a millimeter wave band, disposing the test terminals 116 on the first surface on which antennas are implemented has little influence on the antenna characteristics.

As described, since the high frequency module according to this embodiment has no test wiring or test terminal on the Printed Circuit Board side, the number of terminals in connection members connecting between the module board and the Printed Circuit Board can be kept from increasing while an inspection or failure analysis can be still performed. The high frequency module also does not have to allocate an area for arranging test terminals on the Printed Circuit Board, allowing the Printed Circuit Board to be simple and compact. Moreover, since the test terminals are disposed on the first surface of the module board, ground terminals need not be decreased when the number of test terminals increases and thus degradation in communication performance of the high frequency module can be avoided. Additionally, the high frequency module does not require a special structure such as an opening formed immediately below the module board and is adaptable to devices of varying structures while enabling mounting of test terminals without increasing the areas of boards.

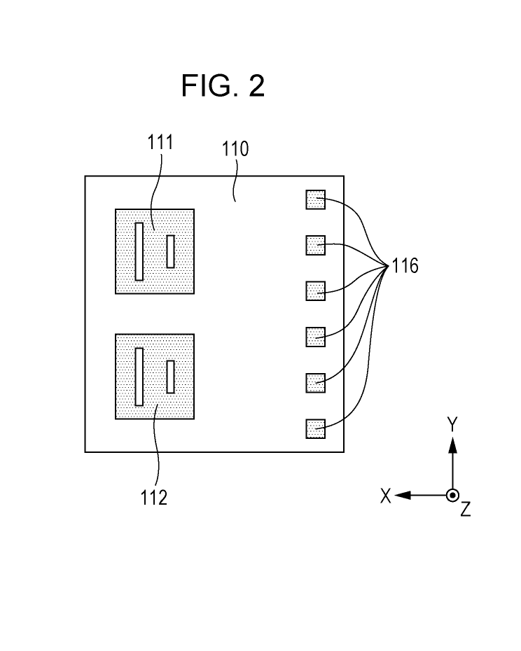

The arrangement of the test terminals 116 on the module board 110 will now be described. FIG. 2 illustrates the first example of arrangement of antennas and test terminals on the module board in the first embodiment.

In the first example, multiple test terminals 116 are arranged in a row along one side of the first surface of the module board 110 relative to the transmit antenna 111 and the receive antenna 112 arranged on the first surface of the board.

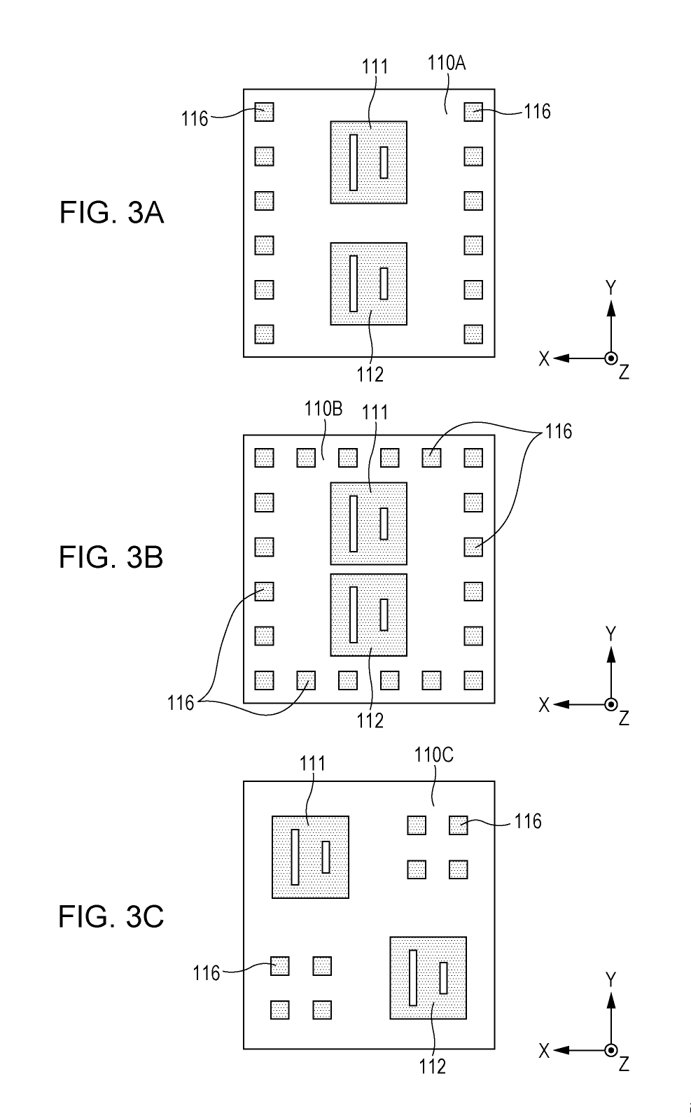

FIG. 3A illustrates the second example of arrangement of antennas and test terminals on the module board in the first embodiment. FIG. 3B illustrates a first variation of the second example of arrangement of antennas and test terminals on the module board in the first embodiment. FIG. 3C illustrates a second variation of the second example of arrangement of antennas and test terminals on the module board in the first embodiment. In the second example, the test terminals 116 are disposed at symmetrical positions about the center of the module board relative to the transmit antenna 111 and the receive antenna 112 arranged on the first surface of the module board. In the illustrated example, the test terminals 116 are disposed on both sides of the antennas, being arranged on multiple sides or at multiple locations on the first surface of the module board.

The module board 110A in FIG. 3A represents an example in which multiple test terminals 116 are arranged in two rows along two opposite sides of the first surface of the board. The module board 110B in FIG. 3B represents an example in which test terminals 116 are arranged on the entire circumference along the four sides of the first surface of the board. The module board 110C in FIG. 3C represents an example in which the transmit antenna 111 and the receive antenna 112 are arranged near two diagonal corners and multiple test terminals 116 are arranged near the remaining two diagonal corners on the first surface of the board.

With multiple test terminals 116 arranged as shown in FIGS. 3A, 3B, and 3C, when test probes 135 are brought into contact with the test terminals 116, the module board 110A, 110B, 110C are pressed at multiple points, so the module board can be stabilized during execution of an inspection or failure analysis on the high frequency module.

In a case where a high frequency module that performs wireless communication in a millimeter wave band has no ground between antennas and test terminals 116, the ends of the antennas are preferably separated from the ends of the test terminals 116 by at least 3λ/4, where λ represents the effective wavelength of the radio signal to be transmitted and received. The test terminals 116 also function as the ground, providing similar effects to the ground when not used as test terminals.

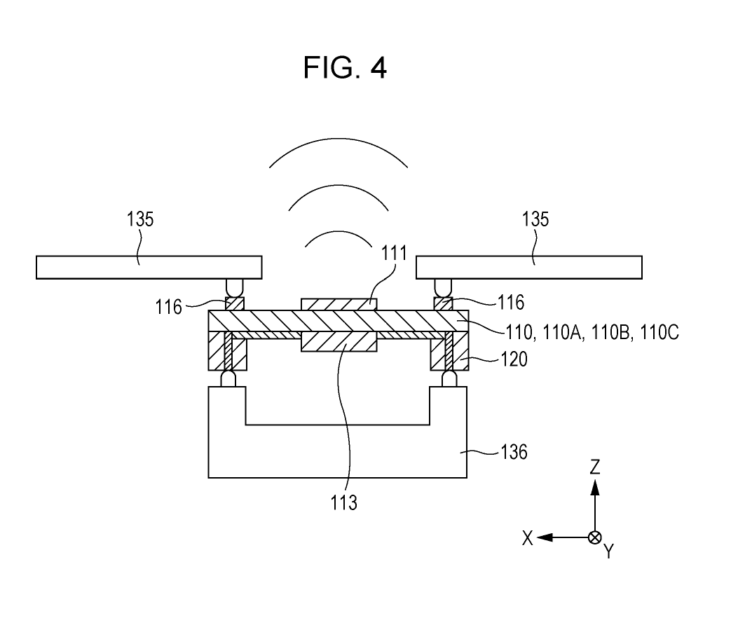

FIG. 4 illustrates the state of contact of the test probes 135 during an inspection or failure analysis on the module board 110.

Preferably, no dielectric or metal is disposed immediately above antennas so that the electromagnetic wave radiation of the antennas is not interfered with when the test probes 135 makes contact with the test terminals 116 on the module board 110 (including 110A, 110B, and 110C, which applies to the following description) while the high frequency module is in operation. In an inspection or failure analysis on the module board 110 alone, meanwhile, the module board 110 is not connected with the Printed Circuit Board 130 but a socket of test equipment is connected to the module board 110 for power supply from the test equipment, ground connection, and signal input/output. To this end, a socket 136 of test equipment is brought into contact with terminals arranged in the connection members 120 on the second surface of the module board 110.

As illustrated in FIG. 4, the socket 136 of the test equipment is connected by applying pressure to the module board 110 to make the terminals of the connection members 120 into contact with the socket 136 to establish electrical conduction between them, rather than being connected by soldering, for example. Accordingly, on the first surface of the module board 110, the test probes 135 are brought into contact in at least two points across the antennas, rather than at a single point. The test probes 135 are preferably pressurized uniformly against the module board 110.

In a case in which electrical conduction is established between the socket 136 of the test equipment and the module board 110 by making them contact each other as illustrated in FIG. 4, the test terminals 116 are preferably arranged on the module board 110 at positions symmetric about the center of the module board 110 across the transmit antenna 111 and the receive antenna 112 as illustrated in FIGS. 3A, 3B, and 3C. When the module board 110 is designed as illustrated in FIG. 3A, 3B, or 3C, the pressure acting on the module board 110 from the test probes 135 becomes uniform, allowing stable contact of the test probes 135.

Thus, this embodiment can provide a high frequency module having inspection or failure analysis functions while avoiding a decrease in ground terminals, keeping the number of terminals in the entire high frequency module and the areas of the boards from increasing, and without requiring a special structure on the Printed Circuit Board.

### Second Embodiment

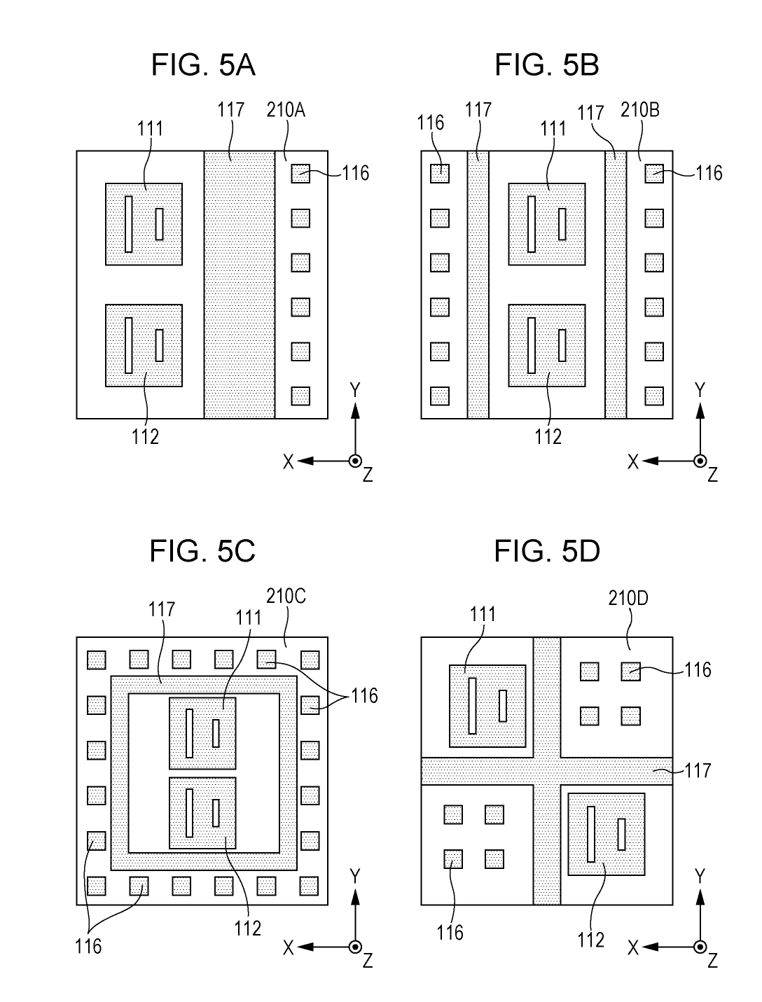

FIG. 5A illustrates the first example of arrangement of antennas and test terminals on the module board of the high frequency module in a second embodiment of the present disclosure. FIG. 5B illustrates the second example of arrangement of antennas and test terminals on the module board of the high frequency module in the second embodiment of the present disclosure. FIG. 5C illustrates the third example of arrangement of antennas and test terminals on the module board of the high frequency module in the second embodiment of the present disclosure. FIG. 5D illustrates the fourth example of arrangement of antennas and test terminals on the module board of the high frequency module in the second embodiment of the present disclosure.

The second embodiment shows an example of providing a ground pattern 117 between the test terminals 116 and the transmit antenna 111 and the receive antenna 112 on the first surface of the module board.

A module board 210A in FIG. 5A represents an example in which the ground pattern 117 is disposed in the shape of a rectangle between test terminals 116 arranged along one side of the first surface of the board and the transmit antenna 111 and the receive antenna 112. A module board 210B in FIG. 5B represents an example in which the ground pattern 117 is disposed in two lines between each row of test terminals 116 arranged along two opposite sides of the first surface of the board and the transmit antenna 111 and the receive antenna 112.

A module board 210C in FIG. 5C represents an example in which the ground pattern 117 is disposed in the shape of a rectangular ring between test terminals 116 arranged on the entire circumference along the four sides of the first surface of the board, and the transmit antenna 111 and the receive antenna 112. A module board 210D in FIG. 5D represents an example in which the ground pattern 117 is disposed in the shape of a cross between test terminals 116 arranged near two diagonal corners of the first surface of the board and the transmit antenna 111 and the receive antenna 112.

By providing the ground pattern 117 on the module board 210, change in antenna characteristics caused by placement of the test terminals 116 on the same side of the module board as the antennas can be minimized.

### Third Embodiment

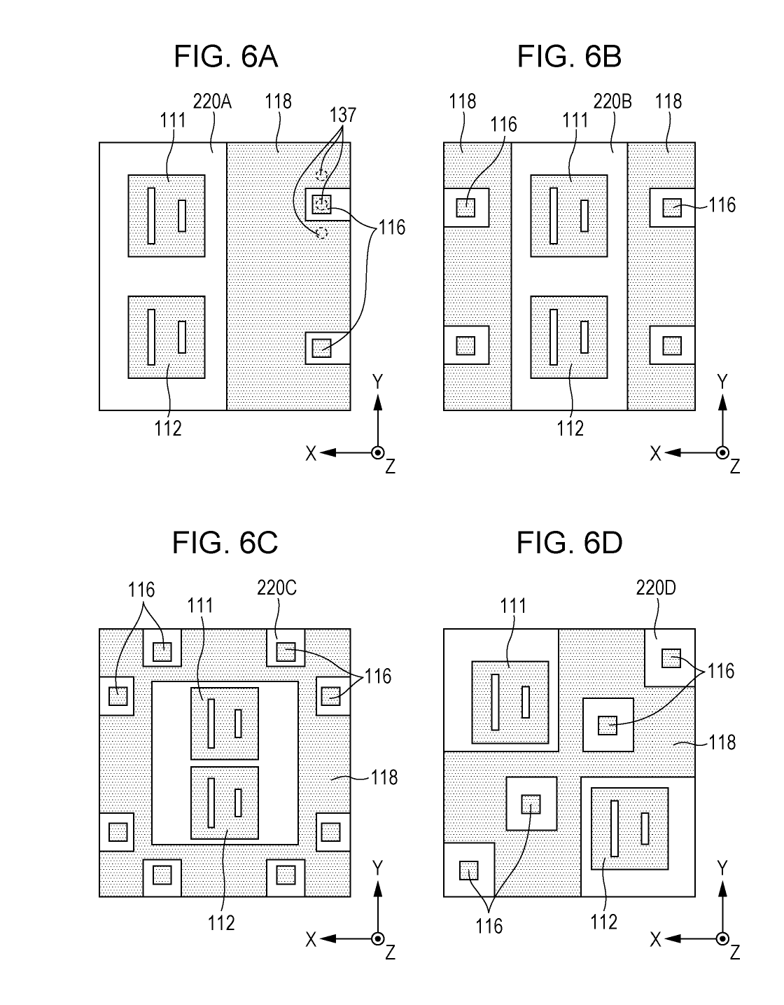

FIG. 6A illustrates the first example of arrangement of antennas and test terminals on the module board of the high frequency module in a third embodiment of the present disclosure. FIG. 6B illustrates the second example of arrangement of antennas and test terminals on the module board of the high frequency module in the third embodiment of the present disclosure. FIG. 6C illustrates the third example of arrangement of antennas and test terminals on the module board of the high frequency module in the third embodiment of the present disclosure. FIG. 6D illustrates the fourth example of arrangement of antennas and test terminals on the module board of the high frequency module in the third embodiment of the present disclosure.

The third embodiment shows an example of providing a ground pattern 118 between the test terminals 116 and the transmit antenna 111 and the receive antenna 112 on the first surface of the module board so as to surround test terminals 116. The ground pattern 118 is formed in a shape surrounding the circumference of a test terminal 116 in at least two directions.

A module board 220A in FIG. 6A represents an example in which a ground pattern 118 surrounding test terminals 116 is disposed between test terminals 116 arranged along one side of the first surface of the board, and the transmit antenna 111 and the receive antenna 112. A module board 220B in FIG. 6B represents an example in which ground patterns 118 surrounding test terminals 116 are disposed between each row of test terminals 116 arranged along two opposite sides of the first surface of the board, and the transmit antenna 111 and the receive antenna 112.

A module board 220C in FIG. 6C represents an example in which a ground pattern 118 surrounding test terminals 116 is disposed between test terminals 116 arranged on the four sides of the first surface of the board, and the transmit antenna 111 and the receive antenna 112. A module board 220D in FIG. 6D represents an example in which a ground pattern 118 surrounding test terminals 116 is disposed between test terminals 116 arranged diagonally on the first surface of the board, and the transmit antenna 111 and the receive antenna 112 respectively arranged near two corners.

Providing the ground pattern 118 surrounding test terminals 116 on the module board 220 also allows contact of a high frequency test probe that has a small interval between the signal terminal and the ground terminal. On the module board 220, the signal wire and the ground are preferably close to each other in order to obtain a desired signal strength (signal amplitude) when a high frequency signal is used.

As shown by probe contact points 137 indicated by broken line circles in FIG. 6A, on a high frequency test probe, ground terminals to make contact with the ground pattern 118 are disposed across a signal terminal which makes contact with a test terminal 116, and the interval between the signal terminal and the ground terminals is small. Thus, the module board 220 also permits an inspection or analysis using high-frequency test signals output by analog circuits in a radio unit (an RF unit), for example, in addition to low-frequency test signals.

While in the module board 220A in FIG. 6A the ground terminals of the test probe are illustrated as being positioned on both sides of the signal terminal in Y-axis direction relative to the test terminals 116, the ground terminal may be provided on one side, or one or more ground terminals may be provided respectively in Y- and X-axis directions relative to the test terminals 116.

### Fourth Embodiment

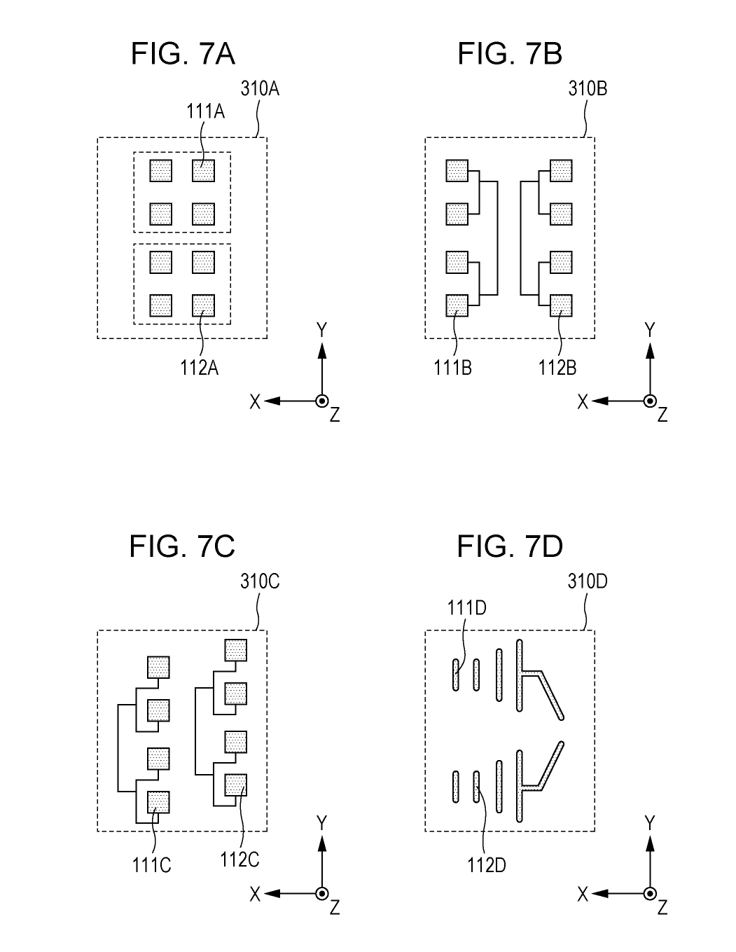

FIG. 7A illustrates the first example of arrangement of antennas on the module board of the high frequency module in a fourth embodiment of the present disclosure. FIG. 7B illustrates the second example of arrangement of antennas on the module board of the high frequency module in the fourth embodiment of the present disclosure. FIG. 7C illustrates the third example of arrangement of antennas on the module board of the high frequency module in the fourth embodiment of the present disclosure. FIG. 7D illustrates the fourth example of arrangement of antennas on the module board of the high frequency module in the fourth embodiment of the present disclosure.

The fourth embodiment shows other arrangements of antennas on the module board of the high frequency module.

An antenna 310A in FIG. 7A represents an example of implementing a transmit antenna 111A and a receive antenna 112A as patch array antennas (micro-strip antennas) which are each formed from four planar antenna elements arranged in a rectangle. The antenna 310A is an antenna having directivity of radiation in the vertical direction (in the positive direction of Z-axis in FIG. 7A) relative to the first surface of the module board.

An antenna 310B in FIG. 7B shows an example of implementing a transmit antenna 111B and a receive antenna 112B as patch array antennas each formed from four planar antenna elements arranged in a row. The antenna 310B has directivity of radiation in the vertical direction (in the positive direction of Z-axis in FIG. 7A) relative to the first surface of the module board, having a different direction of polarization than the antenna 310A in FIG. 7A. For example, when the antenna 310A has vertical polarization, the antenna 310B has horizontal polarization, and vice versa.

An antenna 310C in FIG. 7C shows an example in which a transmit antenna 111B and a receive antenna 112B implemented as patch array antennas each formed from four planar antenna elements arranged in a row are disposed at positions shifted in the arrangement direction of the antenna elements. The antenna 310C is an antenna having directivity of radiation in an oblique direction relative to the antenna 310B of FIG. 7B.

An antenna 310D in FIG. 7D represents an example of providing a transmit antenna 111D and a receive antenna 112D having Yagi antenna characteristics by arranging multiple linear antenna elements in parallel and further providing linear antenna elements wired through the board. The antenna 310D is an antenna having directivity of radiation to the left in the figure (the positive direction of X-axis) in the surface direction of the first surface of the module board (the positive direction of Z-axis in FIG. 7D).

The module board of the high frequency module in this embodiment can be implemented with any of the antenna designs described above.

### Fifth Embodiment

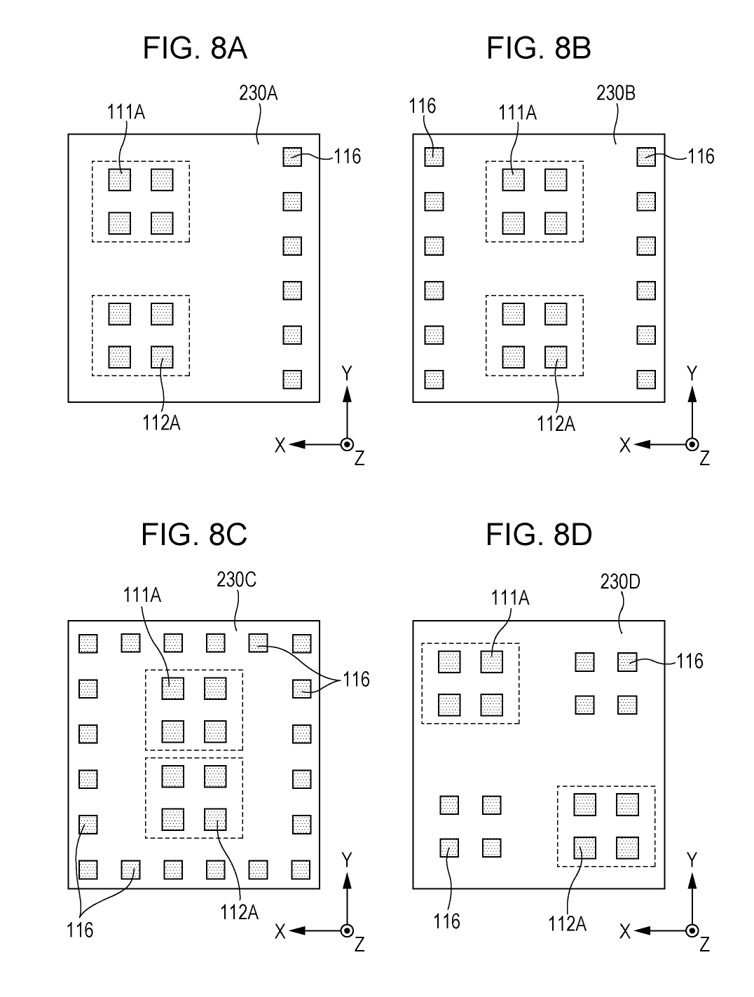

FIG. 8A illustrates the first example of arrangement of antennas and test terminals on the module board of the high frequency module in a fifth embodiment of the present disclosure. FIG. 8B illustrates the second example of arrangement of antennas and test terminals on the module board of the high frequency module in the fifth embodiment of the present disclosure. FIG. 8C illustrates the third example of arrangement of antennas and test terminals on the module board of the high frequency module in the fifth embodiment of the present disclosure. FIG. 8D illustrates the fourth example of arrangement of antennas and test terminals on the module board of the high frequency module in the fifth embodiment of the present disclosure.

The fifth embodiment shows an example of arranging the transmit antenna 111A and the receive antenna 112A shown in FIG. 7A and providing test terminals 116 in a similar manner to the first embodiment illustrated in FIGS. 2, 3A, 3B, and 3C on the first surface of the module board.

A module board 230A in FIG. 8A represents an example of arranging test terminals 116 along one side of the first surface of the board beside the transmit antenna 111A and the receive antenna 112A. A module board 230B in FIG. 8B represents an example in which test terminals 116 are arranged along two opposite sides of the first surface of the board on both sides of the transmit antenna 111A and the receive antenna 112A.

A module board 230C in FIG. 8C represents an example in which test terminals 116 are arranged along the four sides of the first surface of the board around the transmit antenna 111A and the receive antenna 112A. A module board 230D in FIG. 8D represents an example in which the transmit antenna 111A and the receive antenna 112A are arranged near two diagonal corners and test terminals 116 are arranged near the remaining two corners on the first surface of the board.

### Sixth Embodiment

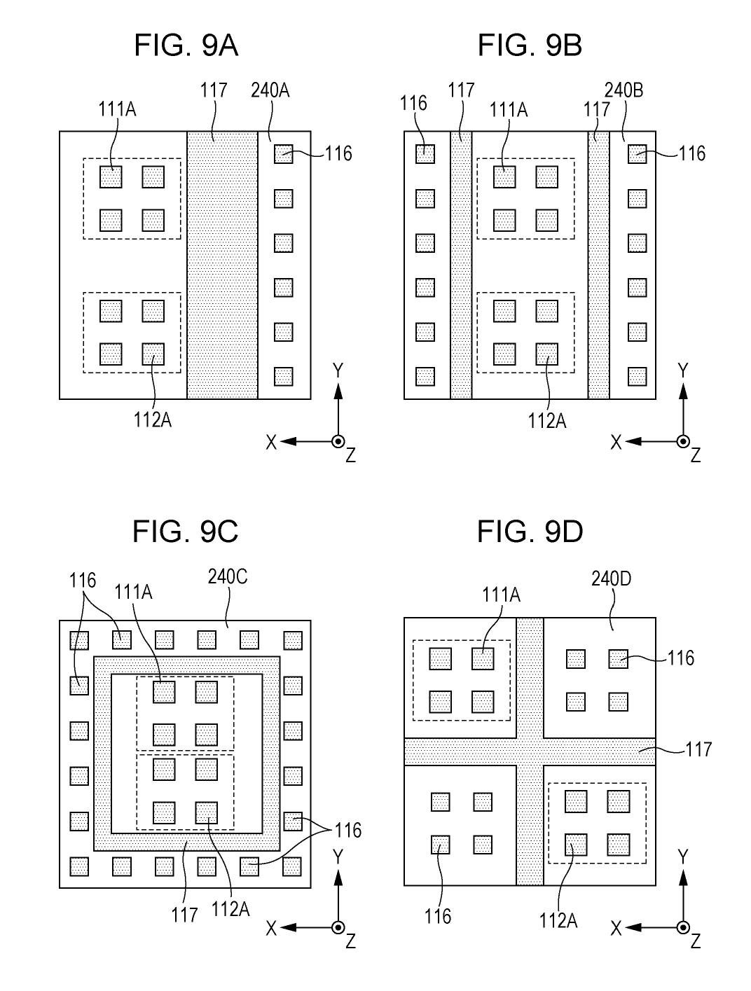

FIG. 9A illustrates the first example of arrangement of antennas and test terminals on the module board of the high frequency module in a sixth embodiment of the present disclosure. FIG. 9B illustrates the second example of arrangement of antennas and test terminals on the module board of the high frequency module in the sixth embodiment of the present disclosure. FIG. 9C illustrates the third example of arrangement of antennas and test terminals on the module board of the high frequency module in the sixth embodiment of the present disclosure. FIG. 9D illustrates the fourth example of arrangement of antennas and test terminals on the module board of the high frequency module in the sixth embodiment of the present disclosure.

The sixth embodiment shows an example of arranging the transmit antenna 111A and the receive antenna 112A shown in FIG. 7A and providing the ground pattern 117 between the antennas and the test terminals 116 in a similar manner to the second embodiment illustrated in FIGS. 5A, 5B, 5C, and 5D on the first surface of the module board.

A module board 240A in FIG. 9A represents an example in which the ground pattern 117 is disposed in the shape of a rectangle between test terminals 116 arranged along one side of the first surface of the board and the transmit antenna 111A and the receive antenna 112A. A module board 240B in FIG. 9B represents an example in which the ground pattern 117 is disposed in two lines between each row of test terminals 116 arranged along two opposite sides of the first surface of the board and the transmit antenna 111A and the receive antenna 112A.

A module board 240C in FIG. 9C represents an example in which the ground pattern 117 is disposed in the shape of a rectangular ring between test terminals 116 arranged on the entire circumference along the four sides of the first surface of the board, and the transmit antenna 111A and the receive antenna 112A. A module board 240D in FIG. 9D represents an example in which the ground pattern 117 is disposed in the shape of a cross between test terminals 116 arranged near two diagonal corners of the first surface of the board and the transmit antenna 111A and the receive antenna 112A.

### Seventh Embodiment

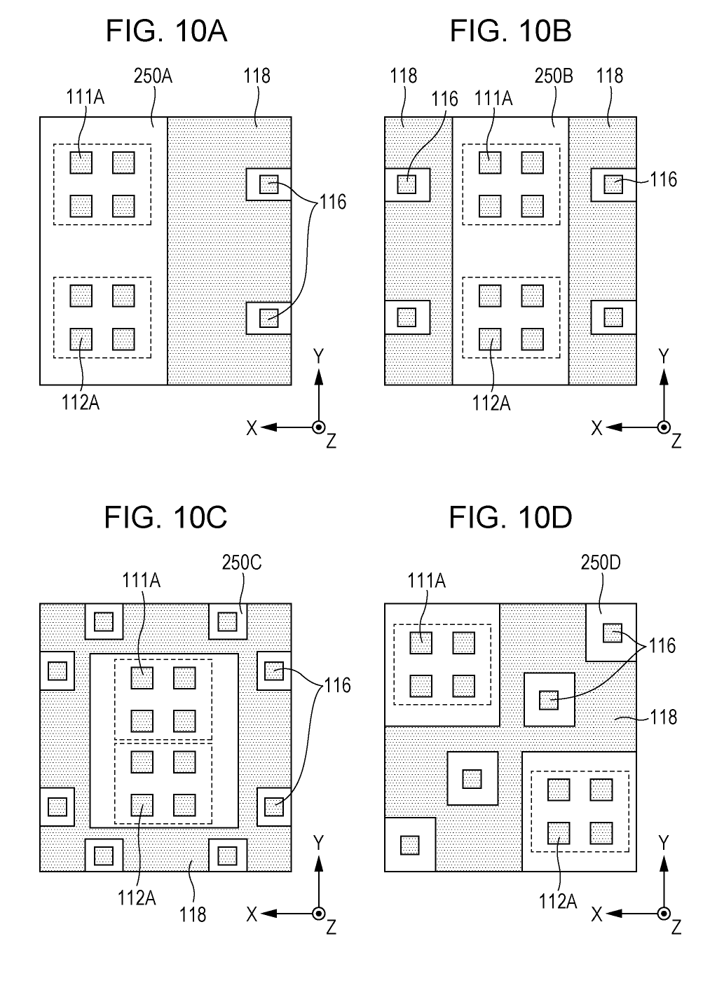

FIG. 10A illustrates the first example of arrangement of antennas and test terminals on the module board of the high frequency module in a seventh embodiment of the present disclosure. FIG. 10B illustrates the second example of arrangement of antennas and test terminals on the module board of the high frequency module in the seventh embodiment of the present disclosure. FIG. 10C illustrates the third example of arrangement of antennas and test terminals on the module board of the high frequency module in the seventh embodiment of the present disclosure. FIG. 10D illustrates the fourth example of arrangement of antennas and test terminals on the module board of the high frequency module in the seventh embodiment of the present disclosure.

The seventh embodiment shows an example of arranging the transmit antenna 111A and the receive antenna 112A shown in FIG. 7A and providing a ground pattern 118 between the antennas and test terminals 116 so as to surround test terminals 116 in a similar manner to the third embodiment illustrated in FIGS. 6A, 6B, 6C, and 6D on the first surface of the module board.

A module board 250A in FIG. 10A represents an example in which a ground pattern 118 surrounding test terminals 116 is disposed between test terminals 116 arranged along one side of the first surface of the board, and the transmit antenna 111A and the receive antenna 112A. A module board 250B in FIG. 10B represents an example in which ground patterns 118 surrounding test terminals 116 are disposed between each row of test terminals 116 arranged along two opposite sides of the first surface of the board, and the transmit antenna 111A and the receive antenna 112A.

A module board 250C in FIG. 10C represents an example in which a ground pattern 118 surrounding test terminals 116 is disposed between test terminals 116 arranged on the four sides of the first surface of the board, and the transmit antenna 111A and the receive antenna 112A. A module board 250D in FIG. 10D represents an example in which a ground pattern 118 surrounding test terminals 116 is disposed between test terminals 116 arranged diagonally on the first surface of the board, and the transmit antenna 111A and the receive antenna 112A respectively arranged near two corners.

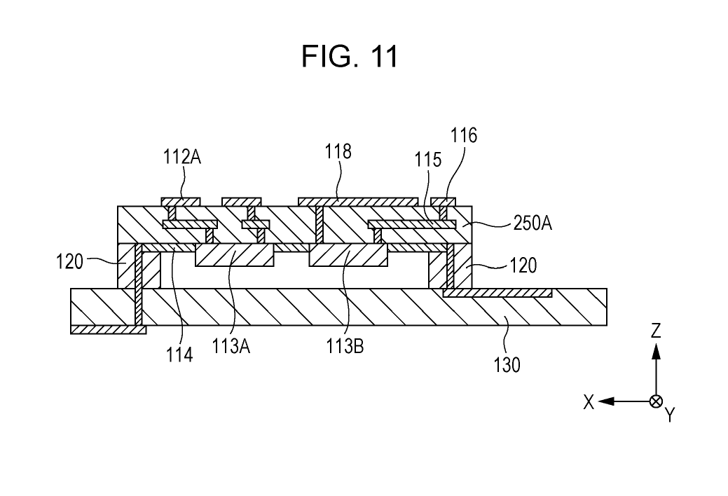

FIG. 11 is a lateral cross-sectional view showing the structure of the high frequency module in the seventh embodiment. Here, an exemplary structure of the high frequency module including the module board 250A of FIG. 10A is shown. In the seventh embodiment, two ICs, an RFIC 113A for processing high frequency signals and a BBIC 113B for processing baseband signals, are implemented as signal processing ICs on the second surface of the module board 250A.

The RFIC 113A is connected with the transmit antenna 111A and the receive antenna 112A on the first surface of the module board 250A and performs frequency conversion (modulation and demodulation), transmission power amplification, received signal amplification, and/or filtering, for example, in relation to transmission and reception processing for high frequency signals. The RFIC 113A is connected with the BBIC 113B and transmits outgoing signals and receives incoming signals. The BBIC 113B performs encoding, decoding, and/or error correction, for example, on outgoing and incoming baseband signals.

The RFIC 113A and BBIC 113B are connected with the Printed Circuit Board 130 via the connection members 120. The RFIC 113A and BBIC 113B are also connected with the test terminals 116 on the first surface of the module board 250A through the test wiring 115.

Also for a high frequency module that has signal processing circuits implemented as multiple ICs on the module board 250A, providing test terminals 116 on the first surface, on which the antennas are mounted, can keep the areas of the connection members 120, the Printed Circuit Board 130, and the module board 250A from increasing and make the module compact. The structure with the RFIC 113A and BBIC 113B arranged on the same board as shown in FIG. 11 can be applied in other embodiments.

### Eighth Embodiment

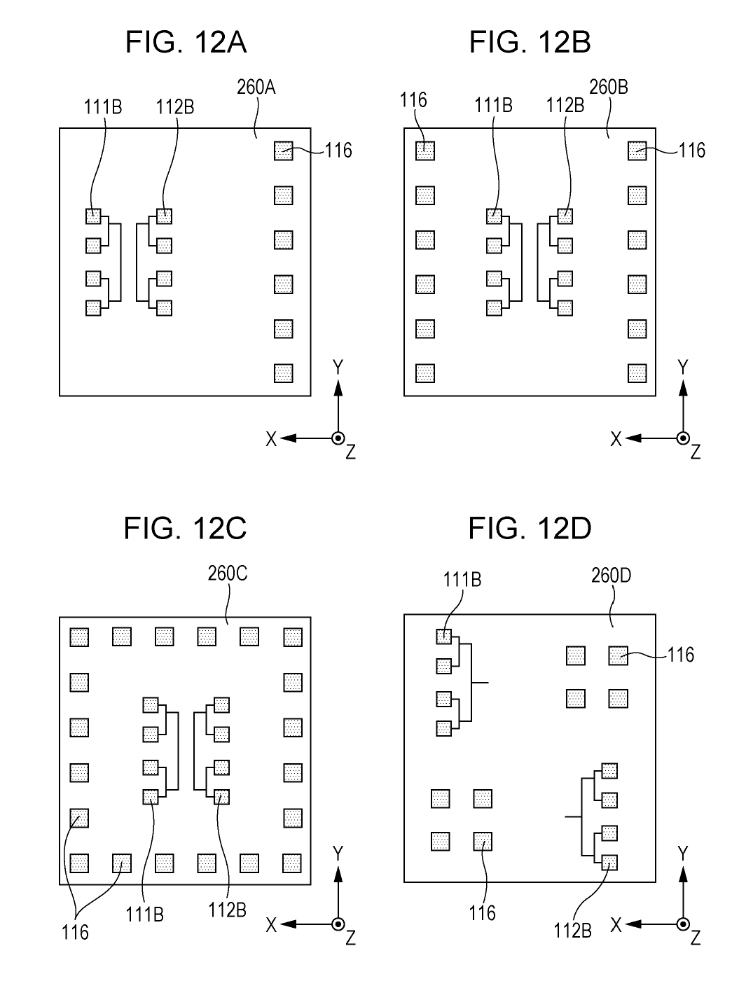

FIG. 12A illustrates the first example of arrangement of antennas and test terminals on the module board of the high frequency module in an eighth embodiment of the present disclosure. FIG. 12B illustrates the second example of arrangement of antennas and test terminals on the module board of the high frequency module in the eighth embodiment of the present disclosure. FIG. 12C illustrates the third example of arrangement of antennas and test terminals on the module board of the high frequency module in the eighth embodiment of the present disclosure. FIG. 12D illustrates the fourth example of arrangement of antennas and test terminals on the module board of the high frequency module in the eighth embodiment of the present disclosure.

The eighth embodiment shows an example of arranging the transmit antenna 111B and the receive antenna 112B shown in FIG. 7B and providing test terminals 116 in a similar manner to the first embodiment illustrated FIGS. 2, 3A, 3B, and 3C on the first surface of the module board.

A module board 260A in FIG. 12A represents an example in which test terminals 116 are arranged along one side of the first surface of the board beside the transmit antenna 111B and the receive antenna 112B. A module board 260B in FIG. 12B represents an example in which test terminals 116 are arranged along two opposite sides of the first surface of the board on both sides of the transmit antenna 111B and the receive antenna 112B.

A module board 260C in FIG. 12C represents an example in which test terminals 116 are arranged along the four sides of the first surface of the board around the transmit antenna 111B and the receive antenna 112B. A module board 260D in FIG. 12D represents an example in which transmit antenna 111B and the receive antenna 112B are arranged near two diagonal corners and test terminals 116 are arranged near the remaining two corners on the first surface of the board.

### Ninth Embodiment

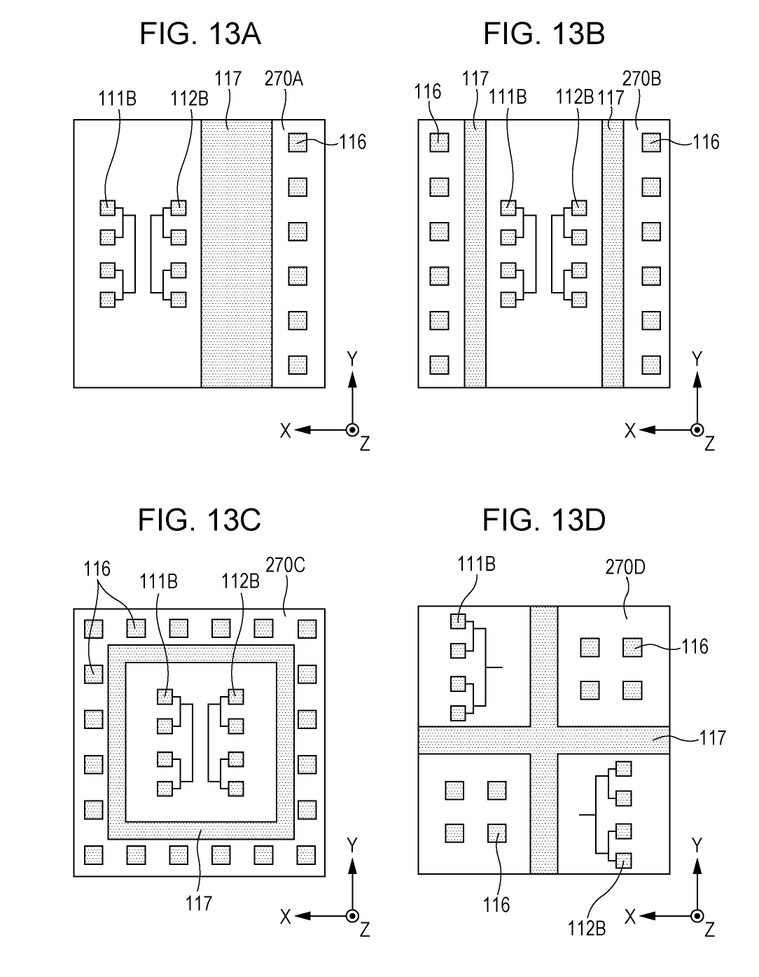

FIG. 13A illustrates the first example of arrangement of antennas and test terminals on the module board of the high frequency module in a ninth embodiment of the present disclosure. FIG. 13B illustrates the second example of arrangement of antennas and test terminals on the module board of the high frequency module in the ninth embodiment of the present disclosure. FIG. 13C illustrates the third example of arrangement of antennas and test terminals on the module board of the high frequency module in the ninth embodiment of the present disclosure. FIG. 13D illustrates the fourth example of arrangement of antennas and test terminals on the module board of the high frequency module in the ninth embodiment of the present disclosure.

The ninth embodiment shows an example of arranging the transmit antenna 111B and the receive antenna 112B shown in FIG. 7B and providing the ground pattern 117 between the antennas and test terminals 116 in a similar manner to the second embodiment illustrated in FIGS. 5A, 5B, 5C, and 5D on the first surface of the module board.

A module board 270A in FIG. 13A represents an example in which the ground pattern 117 is disposed in the shape of a rectangle between test terminals 116 arranged along one side of the first surface of the board and the transmit antenna 111B and the receive antenna 112B. A module board 270B in FIG. 13B represents an example in which the ground pattern 117 is disposed in two lines between each row of test terminals 116 arranged along two opposite sides of the first surface of the board and the transmit antenna 111B and the receive antenna 112B.

A module board 270C in FIG. 13C represents an example in which the ground pattern 117 is disposed in the shape of a rectangular ring between test terminals 116 arranged on the entire circumference along the four sides of the first surface of the board, and the transmit antenna 111B and the receive antenna 112B. A module board 270D in FIG. 13D represents an example in which the ground pattern 117 is disposed in the shape of a cross between test terminals 116 arranged near two diagonal corners of the first surface of the board and the transmit antenna 111B and the receive antenna 112B.

### Tenth Embodiment

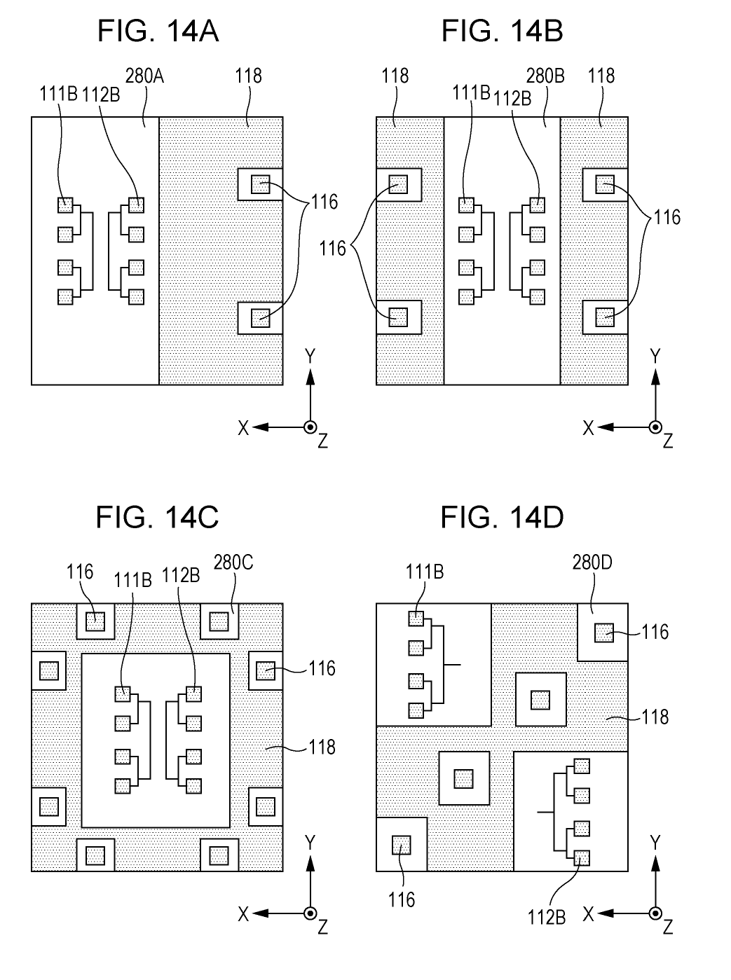

FIG. 14A illustrates the first example of arrangement of antennas and test terminals on the module board of the high frequency module in a tenth embodiment of the present disclosure. FIG. 14B illustrates the second example of arrangement of antennas and test terminals on the module board of the high frequency module in the tenth embodiment of the present disclosure. FIG. 14C illustrates the third example of arrangement of antennas and test terminals on the module board of the high frequency module in the tenth embodiment of the present disclosure. FIG. 14D illustrates the fourth example of arrangement of antennas and test terminals on the module board of the high frequency module in the tenth embodiment of the present disclosure.

The tenth embodiment shows an example of arranging the transmit antenna 111B and the receive antenna 112B shown in FIG. 7B and providing the ground pattern 118 between the antennas and the test terminals 116 so as to surround test terminals 116 in a similar manner to the third embodiment illustrated in FIGS. 6A, 6B, 6C, and 6D on the first surface of the module board.

A module board 280A in FIG. 14A represents an example in which a ground pattern 118 surrounding test terminals 116 is disposed between test terminals 116 arranged along one side of the first surface of the board, and the transmit antenna 111B and the receive antenna 112B. A module board 280B in FIG. 14B represents an example in which ground patterns 118 surrounding test terminals 116 are disposed between each row of test terminals 116 arranged along two opposite sides of the first surface of the board, and the transmit antenna 111B and the receive antenna 112B.

A module board 280C in FIG. 14C represents an example in which a ground pattern 118 surrounding test terminals 116 is disposed between test terminals 116 arranged on the four sides of the first surface of the board, and the transmit antenna 111B and the receive antenna 112B. A module board 280D in FIG. 14D represents an example in which a ground pattern 118 surrounding test terminals 116 is disposed between test terminals 116 arranged diagonally on the first surface of the board, and the transmit antenna 111B and the receive antenna 112B respectively arranged near two corners.

### Eleventh Embodiment

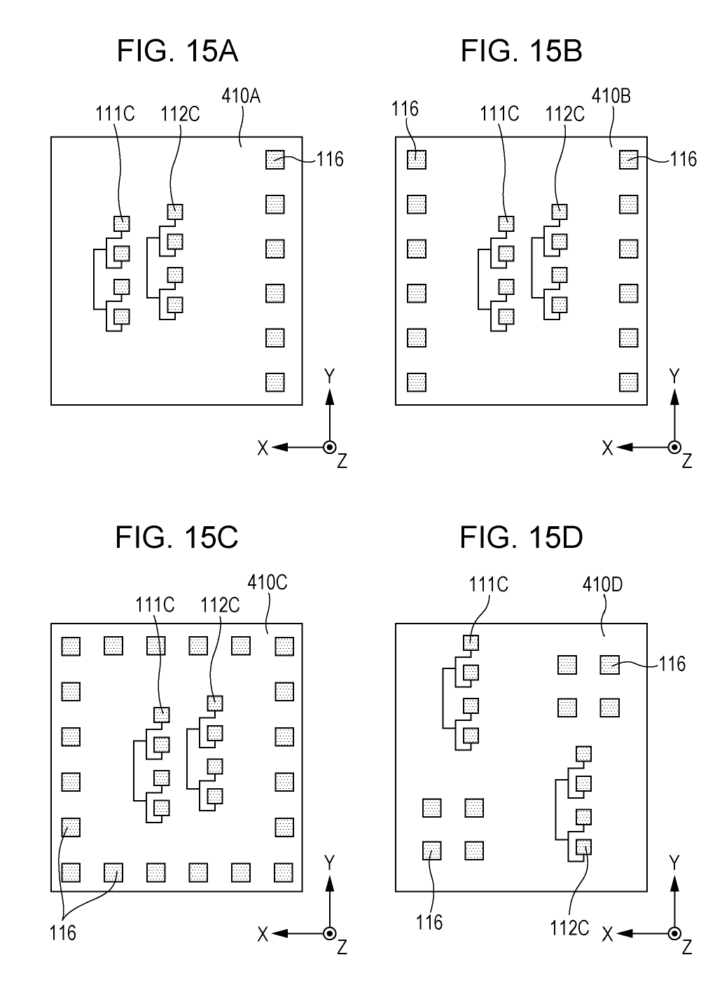

FIG. 15A illustrates the first example of arrangement of antennas and test terminals on the module board of the high frequency module in an eleventh embodiment of the present disclosure. FIG. 15B illustrates the second example of arrangement of antennas and test terminals on the module board of the high frequency module in the eleventh embodiment of the present disclosure. FIG. 15C illustrates the third example of arrangement of antennas and test terminals on the module board of the high frequency module in the eleventh embodiment of the present disclosure. FIG. 15D illustrates the fourth example of arrangement of antennas and test terminals on the module board of the high frequency module in the eleventh embodiment of the present disclosure.

The eleventh embodiment shows an example of arranging the transmit antenna 111C and receive antenna 112C illustrated in FIG. 7C and providing test terminals 116 in a similar manner to the first embodiment illustrated in FIGS. 2, 3A, 3B, and 3C on the first surface of the module board.

A module board 410A in FIG. 15A represents an example of arranging test terminals 116 along one side of the first surface of the board beside the transmit antenna 111C and the receive antenna 112C. A module board 410B in FIG. 15B represents an example in which test terminals 116 are arranged along two opposite sides of the first surface of the board on both sides of the transmit antenna 111C and the receive antenna 112C.

A module board 410C in FIG. 15C represents an example in which test terminals 116 are arranged along the four sides of the first surface of the board around the transmit antenna 111C and receive antenna 112C. A module board 410D in FIG. 15D represents an example in which transmit antenna 111C and receive antenna 112C are arranged near two diagonal corners and test terminals 116 are arranged near the remaining two corners on the first surface of the board.

### Twelfth Embodiment

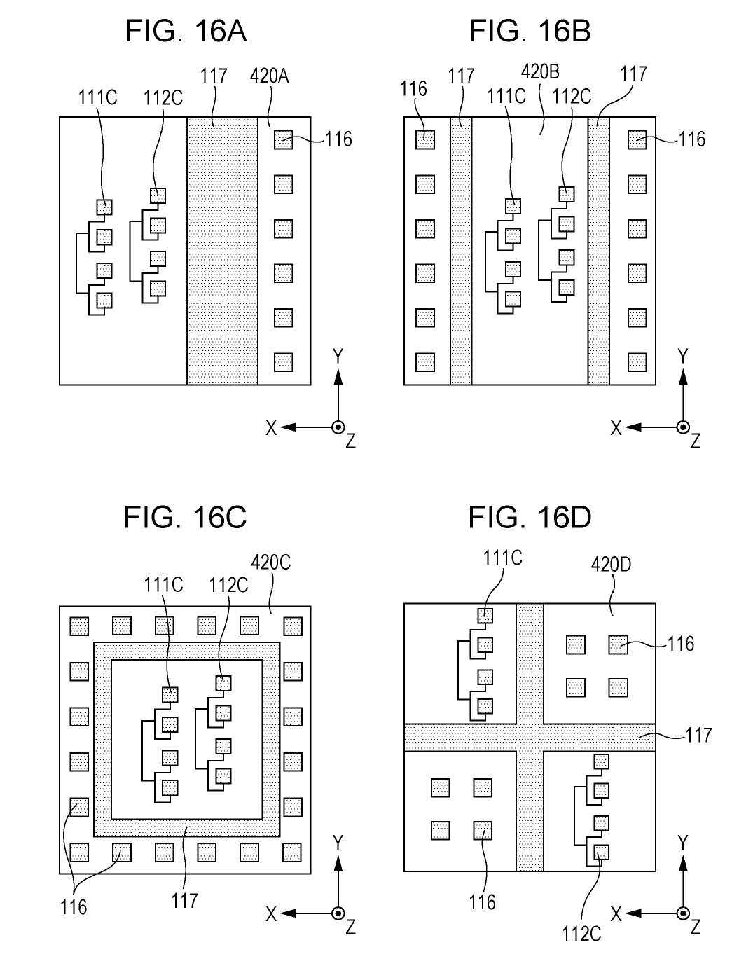

FIG. 16A illustrates the first example of arrangement of antennas and test terminals on the module board of the high frequency module in a twelfth embodiment of the present disclosure. FIG. 16B illustrates the second example of arrangement of antennas and test terminals on the module board of the high frequency module in the twelfth embodiment of the present disclosure. FIG. 16C illustrates the third example of arrangement of antennas and test terminals on the module board of the high frequency module in the twelfth embodiment of the present disclosure. FIG. 16D illustrates the fourth example of arrangement of antennas and test terminals on the module board of the high frequency module in the twelfth embodiment of the present disclosure.

The twelfth embodiment shows an example of arranging the transmit antenna 111C and receive antenna 112C shown in FIG. 7C and providing the ground pattern 117 between the antennas and test terminals 116 in a similar manner to the second embodiment illustrated in FIGS. 5A, 5B, 5C, and 5D on the first surface of the module board.

A module board 420A in FIG. 16A represents an example in which the ground pattern 117 is disposed in the shape of a rectangle between test terminals 116 arranged along one side of the first surface of the board and the transmit antenna 111C and receive antenna 112C. A module board 420B in FIG. 16B represents an example in which the ground pattern 117 is disposed in two lines between each row of test terminals 116 arranged along two opposite sides of the first surface of the board and the transmit antenna 111C and receive antenna 112C.

A module board 420C in FIG. 16C represents an example in which the ground pattern 117 is disposed in the shape of a rectangular ring between test terminals 116 arranged on the entire circumference along the four sides of the first surface of the board, and the transmit antenna 111C and receive antenna 112C. A module board 420D in FIG. 16D represents an example in which the ground pattern 117 is disposed in the shape of a cross between test terminals 116 arranged near two diagonal corners of the first surface of the board, and the transmit antenna 111C and receive antenna 112C.

### Thirteenth Embodiment

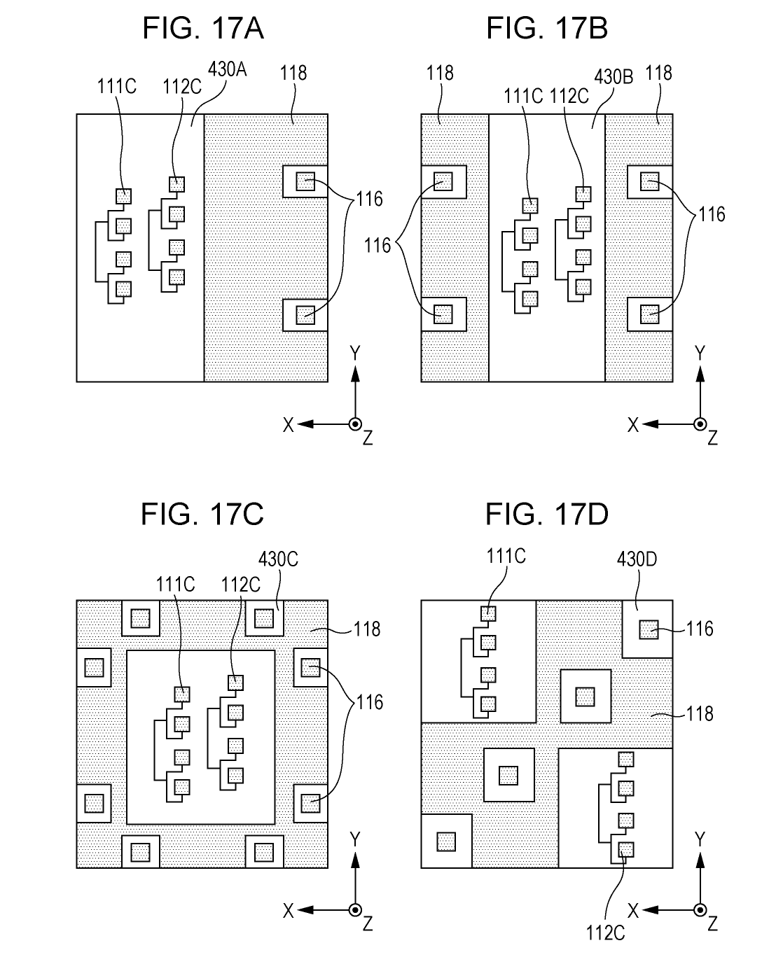

FIG. 17A illustrates the first example of arrangement of antennas and test terminals on the module board of the high frequency module in a thirteenth embodiment of the present disclosure. FIG. 17B illustrates the second example of arrangement of antennas and test terminals on the module board of the high frequency module in the thirteenth embodiment of the present disclosure. FIG. 17C illustrates the third example of arrangement of antennas and test terminals on the module board of the high frequency module in the thirteenth embodiment of the present disclosure. FIG. 17D illustrates the fourth example of arrangement of antennas and test terminals on the module board of the high frequency module in the thirteenth embodiment of the present disclosure.

The thirteenth embodiment shows an example of arranging the transmit antenna 111C and receive antenna 112C illustrated in FIG. 7C and providing the ground pattern 118 between the antennas and test terminals 116 so as to surround test terminals 116 in a similar manner to the third embodiment illustrated in FIGS. 6A, 6B, 6C, and 6D on the first surface of the module board.

A module board 430A in FIG. 17A represents an example in which a ground pattern 118 surrounding test terminals 116 is disposed between test terminals 116 arranged along one side of the first surface of the board, and the transmit antenna 111C and receive antenna 112C. A module board 430B in FIG. 17B represents an example in which ground patterns 118 surrounding test terminals 116 are disposed between each row of test terminals 116 arranged along two opposite sides of the first surface of the board, and the transmit antenna 111C and receive antenna 112C.

A module board 430C in FIG. 17C represents an example in which a ground pattern 118 surrounding test terminals 116 is disposed between test terminals 116 arranged on the four sides of the first surface of the board, and the transmit antenna 111C and receive antenna 112C. A module board 430D in FIG. 17D represents an example in which a ground pattern 118 surrounding test terminals 116 is disposed between test terminals 116 arranged diagonally on the first surface of the board, and transmit antenna 111C and receive antenna 112C respectively arranged near two corners.

### Fourteenth Embodiment

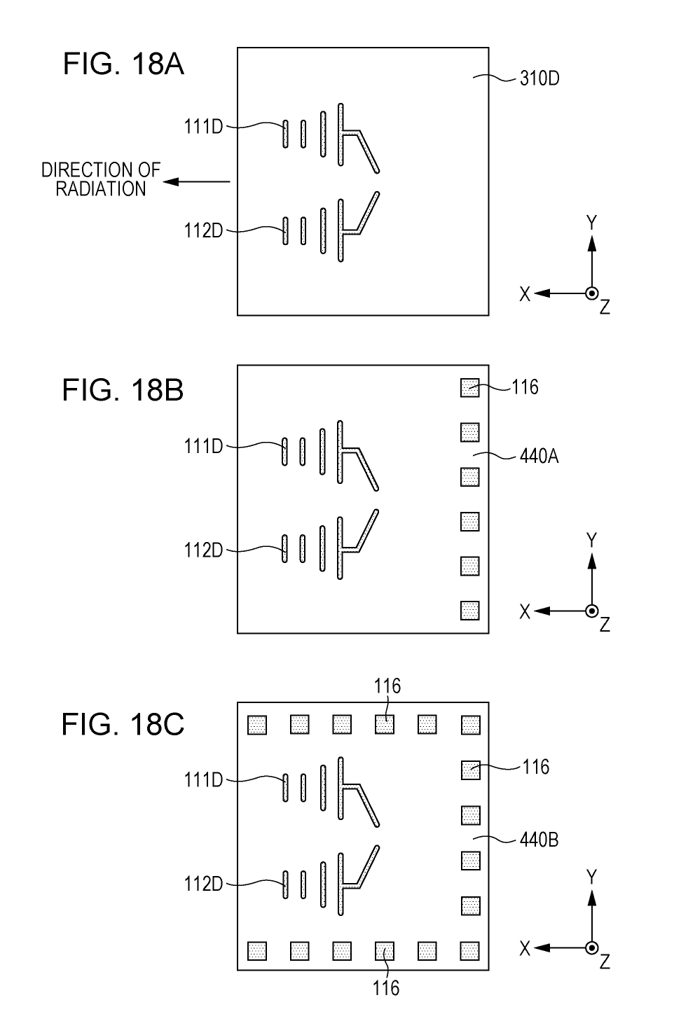

FIG. 18A illustrates the first example of arrangement of antennas and test terminals on the module board of the high frequency module in a fourteenth embodiment of the present disclosure. FIG. 18B illustrates the second example of arrangement of antennas and test terminals on the module board of the high frequency module in the fourteenth embodiment of the present disclosure. FIG. 18C illustrates the third example of arrangement of antennas and test terminals on the module board of the high frequency module in the fourteenth embodiment of the present disclosure.

The fourteenth embodiment shows an example of arranging the transmit antenna 111D and receive antenna 112D illustrated in FIG. 7D and providing test terminals 116 on the first surface of the module board. As illustrated in FIG. 18A, the transmit antenna 111D and the receive antenna 112D have directivity of radiation to the left in the figure (in a lateral direction along the antenna mounted surface, or the positive direction of X-axis) in the surface direction of the first surface of the module board (the positive direction of Z-axis in FIG. 18A). Thus, no test terminals 116 are disposed in the direction of radiation of the antennas (the direction in which they have directivity) on the first surface of the module board.

A module board 440A in FIG. 18B represents an example in which test terminals 116 are arranged along one side of the first surface of the board on the power supply side of the transmit antenna 111D and the receive antenna 112D. A module board 440B in FIG. 18C represents an example in which test terminals 116 are arranged along three sides of the first surface of the board except the direction of radiation of the antennas around the transmit antenna 111D and the receive antenna 112D. The arrangement of test terminals 116 shown in FIG. 18C can be applied in other embodiments in accordance with the direction of radiation.

By thus arranging test terminals 116 excluding the direction of radiation of antennas, influence of the test terminals 116 on the antenna characteristics can be reduced.

### Fifteenth Embodiment

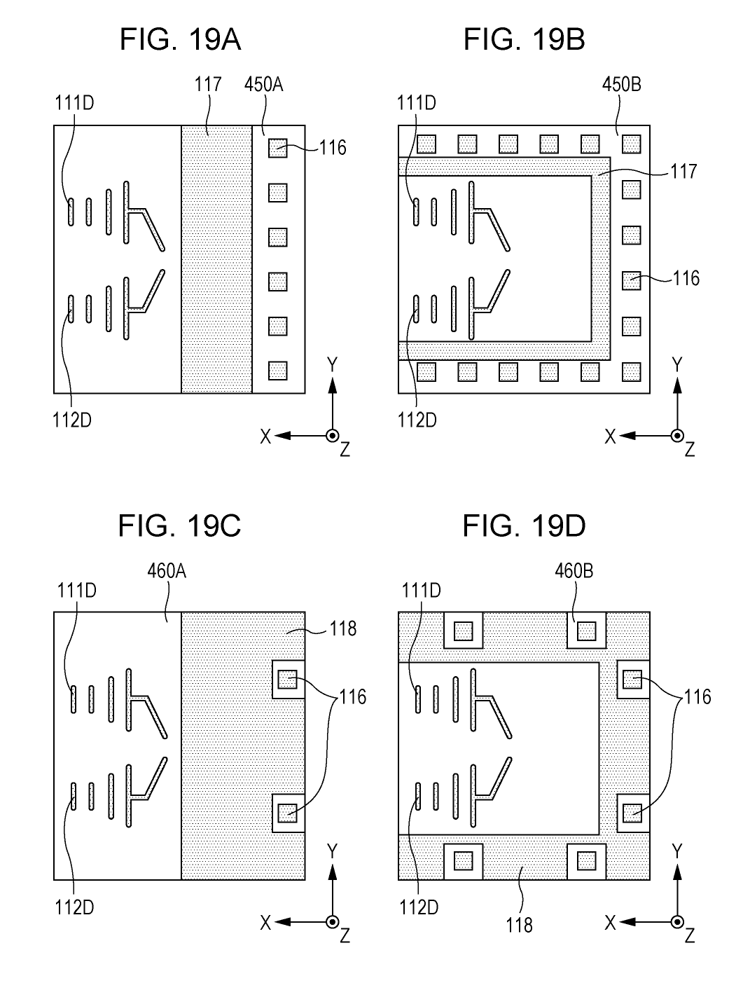

FIG. 19A illustrates the first example of arrangement of antennas and test terminals on the module board of the high frequency module in a fifteenth embodiment of the present disclosure. FIG. 19B illustrates the second example of arrangement of antennas and test terminals on the module board of the high frequency module in the fifteenth embodiment of the present disclosure. FIG. 19C illustrates the third example of arrangement of antennas and test terminals on the module board of the high frequency module in the fifteenth embodiment of the present disclosure. FIG. 19D illustrates the fourth example of arrangement of antennas and test terminals on the module board of the high frequency module in the fifteenth embodiment of the present disclosure.

The fifteenth embodiment shows an example of arranging the transmit antenna 111D and receive antenna 112D shown in FIG. 7D and providing the ground pattern 117 or 118 between the antennas and test terminals 116 on the first surface of the module board.

A module board 450A in FIG. 19A represents an example in which the ground pattern 117 is disposed in the shape of a rectangle between test terminals 116 arranged along one side of the first surface of the board and the transmit antenna 111D and receive antenna 112D. A module board 450B in FIG. 19B represents an example in which the ground pattern 117 is disposed in a U-shape between test terminals 116 arranged along three sides of the first surface of the board except the direction of radiation of the antennas, and the transmit antenna 111D and the receive antenna 112D. The U-shaped ground pattern 117 can be applied in other embodiments in accordance with the direction of radiation.

A module board 460A in FIG. 19C represents an example in which a ground pattern 118 surrounding test terminals 116 is disposed between test terminals 116 arranged along one side of the first surface of the board, and the transmit antenna 111D and receive antenna 112D. A module board 460B in FIG. 19D represents an example in which a ground pattern 118 surrounding test terminals 116 is disposed between test terminals 116 arranged along three sides of the first surface of the board except the direction of radiation of the antennas, and the transmit antenna 111D and receive antenna 112D.

### Sixteenth Embodiment

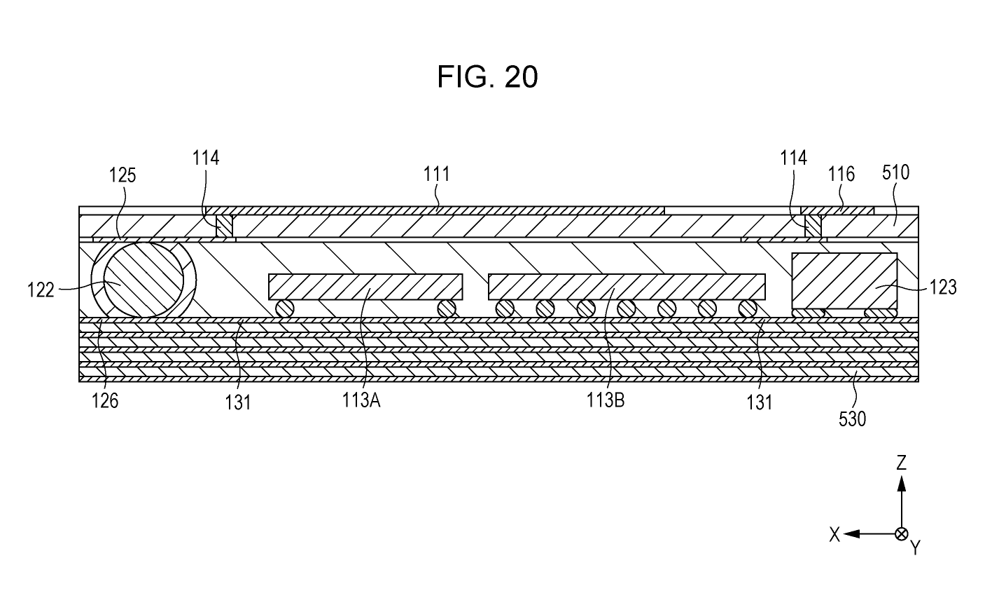

FIG. 20 is a lateral cross-sectional view of the structure of the high frequency module in a sixteenth embodiment. The sixteenth embodiment shows an example of a structure that uses solder plated Cu (copper) core balls as connection members for connecting between a module board 510 and a Printed Circuit Board 530.

On the first surface of the module board 510, a transmit antenna 111 and a receive antenna 112 (not shown) formed of electrically conductive patterns and test terminals 116 are provided. On the second surface of the module board 510, multiple wiring pads 125 composed of pad conductors are formed in the surface direction of the module board 510 (the Y-axis direction in FIG. 20). The transmit antenna 111 and receive antenna 112 and the wiring pads 125, and the test terminals 116 and the wiring pads 125 are connected by circuit wiring 114 including a wiring pattern and through holes.

On the first surface of the Printed Circuit Board 530, multiple wiring pads 126 composed of pad conductors are formed in the surface direction of the Printed Circuit Board 530 (Y-axis direction in FIG. 20) in correspondence with the wiring pads 125 on the module board 510. Also on the first surface of the Printed Circuit Board 530, an RFIC 113A and a BBIC 113B as well as passive elements 123 such as chip capacitors and chip resistors are mounted and connected with the circuit wiring 131 including a wiring pattern and through holes.

A solder plated Cu core ball 122 is mounted on either the wiring pad 125 of the module board 510 or the wiring pad 126 of the Printed Circuit Board 530. The module board 510 and the Printed Circuit Board 530 are electrically connected with each other by melting the solder on the Cu core ball 122 to connect it to the other wiring pad with the module board 510 and the Printed Circuit Board 530 placed opposite each other.

As described above, also for a high frequency module that uses Cu core balls as connection members, providing test terminals 116 on the first surface, on which antennas are mounted, can keep the areas of the Printed Circuit Board 530 and the module board 510 from increasing and make the module compact.

### Seventeenth Embodiment

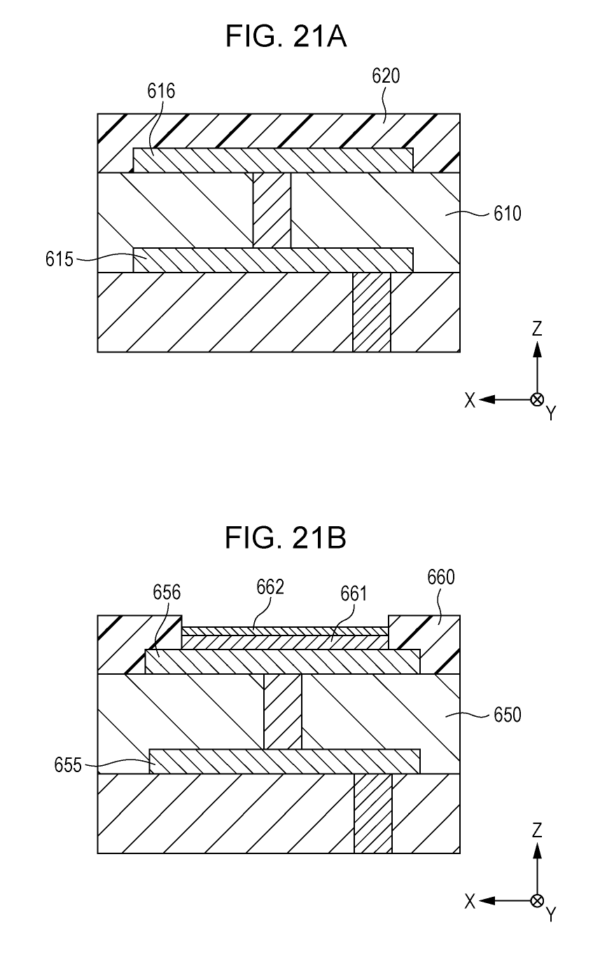

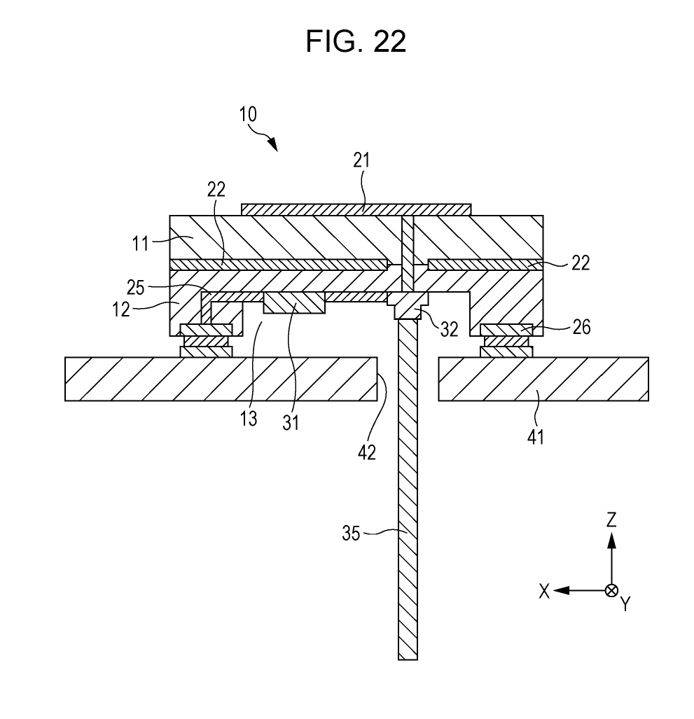

FIG. 21A is a cross-sectional view showing the structure of a test terminal portion of the module board of the high frequency module in a seventeenth embodiment of the present disclosure. FIG. 21B is a cross-sectional view showing a test terminal portion as a comparative example to that of the module board of the high frequency module in the seventeenth embodiment of the present disclosure. The seventeenth embodiment shows an exemplary structure of the area around a test terminal 616 provided on the first surface of a module board 610.

The module board 610 shown in FIG. 21A has a test terminal 616 formed from, for example, a pad conductor mounted thereon, enabling inspection and failure analysis using the test terminal 616. The test terminal 616 is connected with test wiring 615, the other end of which is connected with a signal processing IC (not shown), and test signals are transmitted and received through the test terminal 616.

A solder resist layer 620 composed of dielectric, for example, is formed outside the test terminal 616 so that the test terminal 616 is covered and protected by the solder resist layer 620.

Since communication between the test terminal 616 and probes is not necessary during data transmission and reception, the high frequency module is shipped covered with the solder resist layer 620 and performs data transmission and reception. When the test terminal 616 is used for an inspection or failure analysis of the high frequency module, part of the solder resist layer 620 is scraped away to make the test terminal 616 exposed and the test probe 135 is brought into contact with the test terminal 616.

In a structure in which a test terminal 656 is not fully covered by a solder resist layer 660 and exposed, like a module board 650 shown in FIG. 21B as a comparative example, a nickel plating layer 661 and a gold plating layer 662 are provided outside the test terminal 656 for protection of the test terminal 656.

Since the test terminal 616 is protected by the solder resist layer 620 when the test terminal 616 is not used according to this embodiment shown in FIG. 21A, there is no need to additionally provide metal plating layers such as the nickel plating layer 661 and gold plating layer 662 on the test terminal 616.

This structure of the test terminal 616 and the solder resist layer 620 covering the test terminal 616 can also be applied in other embodiments.

Various aspects of the present disclosure include the followings.

A high frequency module according to a first aspect of the present disclosure includes a module board; antennas disposed on a first surface of the module board; and signal processing circuits disposed on a second surface of the module board which is an opposite side of the first surface of the module board; a connection member connected with the module board and another board and containing wiring for the signal processing circuits; and one or more test terminals connected with the signal processing circuits and disposed on the first surface of the module board.

The high frequency module according to a second aspect of the present disclosure is the high frequency module according to the first aspect, in which an area between the antennas and the one or more test terminals on the module board is covered with resist or dielectric.

The high frequency module according to a third aspect of the present disclosure is the high frequency module according to the first aspect, in which the antennas yield a maximum radiation efficiency in a 30-GHz or higher band.

The high frequency module according to a fourth aspect of the present disclosure is the high frequency module according to the first aspect, in which ends of the antennas are separated from the end of the one or more test terminals by at least a ¾ wavelength.

The high frequency module according to a fifth aspect of the present disclosure is the high frequency module according to the first aspect, in which the one or more test terminals are a terminal distinct from a ground terminal and a plurality of test terminals are arranged on the module board at symmetrical positions about a center of the module board.

The high frequency module according to a sixth aspect of the present disclosure is the high frequency module according to the first aspect, further including a ground pattern disposed on the first surface of the module board between the antennas and the one or more test terminals.

The high frequency module according to a seventh aspect of the present disclosure is the high frequency module according to the sixth aspect, in which the ground pattern is in a shape that surrounds a circumference of the one or more test terminals in at least two directions.

The high frequency module according to an eighth aspect of the present disclosure is the high frequency module according to the first aspect, in which the one or more test terminals are disposed at positions that are not in a direction of maximum radiation of the antennas if the antennas have directivity.

The high frequency module according to a ninth aspect of the present disclosure is the high frequency module according to the first aspect, in which the one or more test terminals are covered with a resist layer.

While various embodiments of the present disclosure have been described with reference to drawings, it will be appreciated that the present disclosure is not limited to those embodiments. It will be apparent to those skilled in the art that various modifications or alterations are conceivable without departing from the scope of claims and it is to be understood that such modifications and alterations are encompassed within the technical scope of the present disclosure. Also, components from different embodiments may be combined without departing from the scope of the present disclosure.

The present disclosure provides a high frequency module that includes a board on which antennas for wireless communication are mounted, and has the advantage of allowing mounting of test terminals while keeping the areas of boards from increasing. The high frequency module is useful as a wireless communication module for high frequency, for example, a millimeter wave band.

What is claimed is:

1. A high frequency module comprising:
a module board;
antennas disposed on a first surface of the module board;
signal processing circuits disposed on a second surface of the module board which is an opposite side of the first surface of the module board;
a connection member connected with the module board and another board and containing wiring for the signal processing circuits; and
one or more test terminals connected with the signal processing circuits and disposed on the first surface of the module board.

2. The high frequency module according to claim 1, wherein an area between the antennas and the one or more test terminals on the module board is covered with resist or dielectric.

3. The high frequency module according to claim 1, wherein the antennas yield a maximum radiation efficiency in a 30-GHz or higher band.

4. The high frequency module according to claim 1, wherein ends of the antennas are separated from the end of the one or more test terminals by at least a ¾ wavelength.

5. The high frequency module according to claim 1, wherein the one or more test terminals are a terminal distinct from a ground terminal and a plurality of test terminals are arranged on the module board at symmetrical positions about a center of the module board.

6. The high frequency module according to claim 1, further comprising:
a ground pattern disposed on the first surface of the module board between the antennas and the one or more test terminals.

7. The high frequency module according to claim 6, wherein the ground pattern is in a shape that surrounds a circumference of the one or more test terminals in at least two directions.

8. The high frequency module according to claim 1, wherein the one or more test terminals are disposed at positions that are not in a direction of maximum radiation of the antennas if the antennas have directivity.

9. The high frequency module according to claim 1, wherein the one or more test terminals are covered with a resist layer.
